(19) United States
(12) Patent Application Publication
(10) Pub. No.: US 2025/0324514 A1
(43) Pub. Date: Oct. 16, 2025

(54) ELECTRONIC MODULES FOR CO-PACKAGED OPTICS AND COPPER PACKAGES

(71) Applicant: Mellanox Technologies, Ltd., Yokneam (IL)

(72) Inventors: Amit OREN, Ramat Hasharon (IL); Barak FREEDMAN, Binyamina (IL); Casper DIETRICH, Roskilde (DK)

(21) Appl. No.: 19/242,145

(22) Filed: Jun. 18, 2025

Related U.S. Application Data
(63) Continuation-in-part of application No. 18/198,890, filed on May 18, 2023.

(51) Int. Cl. H05K 1/18

(52) U.S. Cl. CPC H05K 1/18; H05K 2201/10325; H05K 2201/10674; H05K 2201/10734

(57) ABSTRACT

An example electronic module includes a multi-chip module (MCM) substrate comprising a central portion configured to receive a main die; a plurality of MCM sockets positioned about a peripheral portion of the MCM substrate; and a plurality of mezzanine packages coupled to respective MCM sockets of the plurality of MCM sockets. The plurality of MCM sockets and the MCM substrate are configured to enable communication of digital data between the main die and respective mezzanine packages of the plurality of mezzanine packages. The plurality of mezzanine packages includes at least one co-packaged copper (CPC) package; and at least one co-packaged optics (CPO) package.

### CROSS-REFERENCE TO RELATED APPLICATION(S)

This application is a continuation-in-part of U.S. application Ser. No. 18/198,890, filed May 18, 2023, the content of which is incorporated herein by reference in its entirety.

### FIELD

Various embodiments relate to electronic modules for co-packaged optics and copper packages and methods of making the same.

### BACKGROUND

As bandwidth requirements increase, the number of high-speed channels running to and from ASICs of electronic modules increase along with the power consumption of the electronic modules. To increase the number of high-speed channels and accommodate the increased power consumption, electronic module designers increase the number of electrical connections provided by ball grid arrays of the electronic modules, which increases the overall substrate size of the electronic modules.

### GENERAL DESCRIPTION

The following presents a simplified summary of one or more embodiments of the present disclosure, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present disclosure in a simplified form as a prelude to the more detailed description that is presented later.

Datacenters and computing clusters rely on a fast and robust communication infrastructure. This is achieved by using optical interconnects and/or cable interconnects. As data processing requests of datacenters continues to increase, so does the number of high-speed channels to and from various processing units and/or switches of datacenters and computing clusters.

Various embodiments provide an electronic module configured to enable cable interconnect and optical interconnect channels for communicating with a computing resource such as an application specific integrated circuit (ASIC), a processing unit (e.g., central processing unit (CPU), graphic processing unit (GPU), data processing unit (DPU), parallel processing unit (PPU), quantum processing unit (QPU), and/or the like), switch, or other computing resource. In various embodiments, the electronic module includes a multi-chip module (MCM) substrate including a central portion configured to receive a main die, and a plurality of MCM sockets positioned about a peripheral portion of the MCM substrate. A plurality of mezzanine packages are coupled to respective MCM sockets of the plurality of MCM sockets. The plurality of MCM sockets and the MCM substrate are configured to enable communication of digital data between the main die and the respective mezzanine packages (e.g., via traces of the MCM substrate, and/or the like). The plurality of mezzanine packages include at least one co-packaged copper (CPC) package and at least one co-packaged optical (CPO) package.

The disclosed systems and methods may be implemented using co-packaged optical (CPO) solutions integrated with electronic switch ASICs, network processors, or AI accelerators. Optical components such as modulators, drivers, photodetectors, and laser sources may be co-packaged directly on or near the host silicon using advanced packaging technologies including 2.5D interposers or silicon bridges.

In some configurations, mid-board optical modules (MBOMs) are employed as part of the optical I/O strategy. MBOMs are positioned centrally on the PCB—between the front panel and the host die—enabling shorter electrical traces and improved signal integrity while maintaining separation between optics and high-power ASICs for thermal management.

Near-packaged optics may also be used, placing optical engines in close proximity to the host device without full co-packaging, allowing for modular deployment and gradual migration from pluggable optics.

The system may support optical connectivity through edge couplers, fiber ribbon interfaces, or on-board photonic waveguides. Silicon photonics may be used to implement optical engines within the CPO or MBOM units, with support for modulation schemes such as PAM4, coherent signaling, or WDM.

These components may be interconnected via high-speed electrical interfaces such as SerDes lanes, and coordinated via on-board controllers that handle lane training, optical power tuning, and health monitoring.

Embodiments may scale from 400 G to 1.6 T and beyond, supporting deployment in high-performance computing, AI clusters, and data center switching platforms. Integration strategies may include air-cooled and liquid-cooled packages, supporting advanced thermal designs to handle the combined electrical and optical power densities.

The system may be implemented in modular switch platforms, AI training fabrics, or other environments requiring high-density, low-latency interconnect.

In various embodiments, at least one mezzanine package of the plurality of mezzanine packages is configured to be powered independent of the MCM substrate. For example, the MCM substrate may be configured to be coupled to a system printed circuit board (PCB) and the at least one mezzanine package may be configured to be powered via a direct electrical connection to the system PCB.

The MCM substrate may have (i) a first surface including a ball grid array (BGA) configured to be connected to a system PCB and (ii) a second surface opposite the first surface, where the second surface defines the central portion and the peripheral portion. The MCM substrate may further include electrical traces. The main die may be positioned on the central portion of the second surface of the MCM substrate and may be in electrical communication with the electrical traces. The plurality of MCM sockets may be positioned on the peripheral portion of the MCM substrate, where each MCM socket of the plurality of MCM sockets is in electrical communication with the electrical traces of the MCM substrate. For example, the electrical traces are configured to place respective MCM sockets (e.g., mezzanine packages coupled to respective MCM sockets) into electrical communication with the main die. The plurality of MCM sockets may be configured to engage and support a mezzanine package substrate via a connector portion of the mezzanine package substrate such that a main portion of the mezzanine package substrate extends beyond the peripheral portion of the MCM substrate. The plurality of MCM sockets may be configured to electrically connect the mezzanine package substrate to the main die via at least one of the electrical traces of the MCM substrate.

In various embodiments, at least a subset of the plurality of mezzanine packages are powered independently of the BGA and/or the MCM substrate. For example, the electrical traces of the MCM substrate are configured to communication of digital data between the plurality of mezzanine packages and the main die. For example, each MCM socket of the plurality of MCM sockets is configured to electrically connect high speed signal pins and ground isolation pins of a respective mezzanine package of the plurality of mezzanine packages to corresponding components of the MCM substrate and the MCM socket is free of power rails.

In some embodiments, each socket of the plurality of MCM sockets may include a socket frame defining a peripheral access opening that may be configured to allow the main portion of the mezzanine package substrate to extend beyond an edge of the MCM socket. Additionally, or alternatively, each socket of the plurality of MCM sockets may include a socket pin array within the socket frame and configured to engage the second surface of the MCM substrate and electrically connect the mezzanine package substrate to the main die via at least one of the electrical traces of the MCM substrate. In some embodiments, a pitch of the BGA may be greater than a pitch of the socket pin array.

In some embodiments, the electronic module may include an attachment member configured to be applied to a connector portion of at least one mezzanine package substrate so as to mechanically secure the at least one of the mezzanine package substrate with respect to a corresponding one of the plurality of MCM sockets, where the attachment member is configured to be attached to the system PCB. Additionally, or alternatively, the attachment member may be a contiguous element configured to simultaneously secure a plurality of connector portions of mezzanine package substrates in the corresponding plurality of MCM sockets.

In some embodiments, the plurality of MCM sockets may be configured to electrically connect high speed signal pins and ground isolation pins of mezzanine package substrates to the MCM.

In at least one example embodiment, an electronic module (including at least one CPO package and at least one CPC package) is part of a datacenter that corresponds to a collection of network devices, such as network switches (e.g., Ethernet switches, IP routers, multiservice platforms, various transmission network elements, legacy communication equipment, or in any other suitable communication system) connected with a collection of servers or compute nodes. A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter may adhere to a networking topology (e.g., a hierarchal networking topology), such as a fat tree topology, a Slim Fly topology, a Dragonfly topology, and/or the like. The datacenter routes traffic amongst the network switches and servers therein, and at least one layer of the topology in the datacenter is coupled to the communication network to allow networking traffic to flow between the datacenter and the network device(s).

The CPO package(s) and CPC package(s) of the electronic module are configured to enabled optical communication (e.g., a CPO package may comprise a transceiver of an optical interconnect) or cabled and/or electronic communication (e.g., a CPC package may comprise a cable connector) with the electronic module and/or a main die electrically coupled to the electronic module. For example, a CPO package may be configured to receive an optical fiber as part of Quad Small Form-factor Pluggable (QSFP) connector, Small Form Pluggable (SFP) connector, or the like. Furthermore, the substrate hosting the electronic module (e.g., the MCM substrate) may be substantially rectangular shape and/or may be dimensioned (e.g., sized, and shaped) for use in any communication system regardless of geometric constraints (e.g., L-shaped, squared-shaped, etc.). A CPC package may include a cable connector configured to have a radiofrequency (RF) cable (e.g., a cable configured for carrying RF electrical signals) inserted therein.

In various embodiments, a CPO package configured for receiving an optical fiber may be implemented in a flip-chip configuration. In certain embodiments, the CPO package is configured as a flip-chip component such that a longitudinal axis of the first adiabatic transition profile of the CPO package and a longitudinal axis of the second adiabatic transition profile of the CPO package may be collinear. Said differently, the orientation of the CPO package in such an embodiment does not require a mirror or other reflective surface to redirect optical signals between the electro-optical component and the receiving surface. As would be evident to one of ordinary skill in the art in light of the present disclosure, however, the CPO package in a flip-chip configuration may also include one or more mirrors (e.g., reflective surfaces) to accommodate optical fibers received at varying angles. In some embodiments, only mirrors may be operationally configured to redirect light given that at some bending radii, light may remain confined to the waveguide. Accordingly, in certain embodiments of a mezzanine package (e.g., CPO package and/or CPC package) of the electronic module may be field replaceable modular packages.

In some embodiments, the mezzanine packages are typically used to connect network-connected devices (e.g., remote client switches, network adapters such as Network Interface controllers (NICs) and Host Channel Adapters (HCAs), Smart-NICs (NICs having embedded CPUs), network-enabled Graphics Processing Units (GPUs), and the like). The terms “network-connected device” and “network device” are used interchangeably herein.

Various embodiments relate to interconnects (e.g., interconnect topologies) that are scalable and advantageous for networks that require a large number of all-to-all or point-to-point links between one or more node or send/receive pairs. In particular, silicon photonics interconnects or topologies are provided herein that may achieve at least moderate bandwidth between many nodes with physical, optical fiber connections. In some implementations, the one or more node or send/receive pairs are coupled with an optical fiber allowing a single wavelength to pass therebetween. In other implementations, multiple wavelengths or groups of wavelengths may be transmitted or received by nodes while simultaneously passing multiple wavelengths or groups of wavelengths to other nodes via optical fiber loops connecting three or more nodes. In some implementations, such interconnects as described herein do not rely on or include one or more of the following: wavelength synchronization between transmit and receive pairs, arbitration of the fiber(s), demultiplexers on the receiver side, and/or an optical crossbar. In some implementations, the optical interconnects may be sized to fit a face-plate form factor or as a mid-board optical connector or co-packaged optics. In some embodiments, the present disclosure provides optical interconnects for high bandwidth density applications like switches and GPUs or other processing elements. In one example, the processing elements may include CPUs, GPUs, DPUs, QPUs, a plurality of PPUs, and ASICs. QPUs are configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

A “node” as described herein may refer to a network switch to which a plurality of CPUs, GPUs, DPUs, or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode or multi-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally, include electrical components. For instance, the device can include electrical connections for applying a potential or current to a waveguide, controlling active optical components, such as modulators, for example, and/or for controlling other components on the optical device.

According to an aspect of the present disclosure, an electronic module is provided. The electronic module includes a multi-chip module (MCM) substrate comprising a central portion configured to receive a main die; a plurality of MCM sockets positioned about a peripheral portion of the MCM substrate; and a plurality of mezzanine packages coupled to respective MCM sockets of the plurality of MCM sockets. The plurality of MCM sockets and the MCM substrate are configured to enable communication of digital data between the main die and respective mezzanine packages of the plurality of mezzanine packages. The plurality of mezzanine packages includes at least one co-packaged copper (CPC) package; and at least one co-packaged optics (CPO) package.

In an example embodiment, at least one mezzanine package of the plurality of mezzanine packages is configured to be powered independent of the MCM substrate.

In an example embodiment, the MCM substrate is configured to be coupled to a system printed circuit board (PCB) and the at least one mezzanine package is configured to be powered via a direct electrical connection to the system PCB.

In an example embodiment, the MCM substrate is configured to be in electrical communication with a system PCB via a ball grid array (BGA) and at least one mezzanine package of the plurality of mezzanine packages is configured to be powered independent of the BGA.

In an example embodiment, the at least one CPC package comprises one or more radio-frequency copper cable connectors and the at least one CPO package comprises one or more optical devices.

In-an example embodiment, each mezzanine package of the plurality of mezzanine packages comprises a respective mezzanine package substrate, the mezzanine package substrate comprises a connector portion configured to engage an MCM socket of the plurality of MCM sockets and a main portion-configured to extend beyond the MCM substrate and configured to host one or more devices of the mezzanine.

In an example embodiment, the MCM substrate is configured to be coupled to a system printed circuit board (PCB) and for at least one mezzanine package of the plurality of mezzanine packages, the one or more devices are powered via an electrical connection between the main portion of the mezzanine package substrate and the system PCB.

In an example embodiment, for at least one mezzanine package of the plurality of mezzanine packages, the one or more devices are configured to communicate data with the main die via the engagement of the socket portion and the MCM socket.

In an example embodiment, the at least one CPO package comprises an input/output connection positioned on the main portion of the mezzanine package substrate, and wherein the input/output connection is configured to transmit input/output signals between the CPO package and a system printed circuit board (PCB), wherein the MCM substrate is configured to be coupled to the system PCB.

In an example embodiment, for at least one mezzanine package of the plurality of mezzanine packages, the one or more devices are flip-chip mounted on the mezzanine package substrate.

In an example embodiment, for the at least one CPO package, the one or more devices comprises one or more photonic integrated circuits (PICs).

In an example embodiment, the at least one CPO package comprises, for each PIC of the one or more PICS, an optical connector.

In an example embodiment, the electronic module further includes a support member configured to be positioned between the main portion of the mezzanine package substrate and a system printed circuit board (PCB) to which the MCM substrate is coupled and to mechanically support the main portion of the mezzanine package substrate with respect to the system PCB.

In an example embodiment, each MCM socket of the plurality of MCM sockets comprises a socket frame defining a peripheral access opening configured to allow the main portion of the mezzanine package substrate to extend beyond an edge of the MCM socket.

In an example embodiment, the electronic module further includes the main die positioned on the central portion of the MCM substrate.

In an example embodiment, each MCM socket of the plurality of MCM sockets comprises a socket pin array configured to electrically connect a respective mezzanine package of the plurality of mezzanine packages to the main die via at least one electrical trace of the MCM substrate.

In an example embodiment, the MCM substrate is configured to be in electrical communication with a system printed circuit board (PCB) via a ball grid array (BGA) and a pitch of the BGA is greater than a pitch of the socket pin array.

In an example embodiment, at least a subset of the plurality of mezzanine packages are configured for at least one of receiving digital data to be provided to the main die or transmitting digital data provided by the main die.

In an example embodiment, each MCM socket of the plurality of MCM sockets is configured to electrically connect high speed signal pins and ground isolation pins of a respective mezzanine package of the plurality of mezzanine packages to corresponding components of the MCM substrate and the MCM socket is free of power rails.

In an example embodiment, at least one MCM socket of the plurality of MCM sockets is configured to have a mezzanine package coupled thereto wherein the mezzanine package is selected from the group consisting of a co-packaged copper (CPC) package and a co-packaged optics (CPO) package.

According to another aspect of the present disclosure, a datacenter or computing cluster including at least one electronic module according to an example embodiment, is provided.

The features, functions, and advantages that have been discussed may be achieved independently in various embodiments of the present disclosure or may be combined with yet other embodiments, further details of which may be seen with reference to the following description and drawings.

### BRIEF DESCRIPTION OF THE DRAWINGS

Having thus described embodiments of the disclosure in general terms, reference will now be made the accompanying drawings, wherein:

FIG. 1A is a top view of a multi-chip module (MCM), in accordance with an example embodiment;

FIG. 1B is a bottom view of the MCM of FIG. 1A;

FIG. 1C is a top view of a co-packaged copper (CPC) package, in accordance with an example embodiment;

FIG. 1D is a top view of a co-packaged optics (CPO) package, in accordance with an example embodiment;

FIG. 1E is a top view of an electronic module including the MCM of FIG. 1A, multiple CPC packages, and multiple CPO packages, in accordance with an example embodiment;

FIG. 1F is a top view of the electronic module of FIG. 1E and an attachment member, in accordance with an example embodiment;

FIG. 1G is a perspective view of an electronic device including the MCM of FIG. 1A, multiple CPC packages, and an attachment member, in accordance with an example embodiment;

FIG. 2 is a cross-sectional view of an electronic device including an MCM and a CPC package, in accordance with an example embodiment;

FIG. 3A is a cross-sectional view of an electronic device including an MCM and a CPO package, in accordance with an example embodiment;

FIG. 3B is a cross-sectional view of an electronic device including an MCM and another CPO package, in accordance with an example embodiment;

FIG. 3C is a cross-sectional view of an electronic device including an MCM and a CPO package including flip-chip mounted optical devices;

FIG. 4A is a perspective view of a socket for an MCM, in accordance with an example embodiment;

FIG. 4B is a bottom view of a connector portion of a mezzanine package substrate, in accordance with an example embodiment;

FIG. 5 is a flowchart illustrating a method of assembling an electronic device, in accordance with an example embodiment;

FIG. 6 provides a block diagram of an example system that may include one or more optical interconnects including integrated clock frequency comb devices, according to certain embodiments;

FIG. 7 provides a schematic diagram of an example datacenter that may include one or more optical interconnects according to certain embodiments;

FIG. 8 provides a block diagram of two example communication devices in communication with one another according to certain embodiments;

FIG. 9 depicts some exemplary scenarios for use of an optical transceiver, in accordance with various embodiments;

FIG. 10 provides a block diagram that schematically illustrates a computing system that may include one or more optical interconnects of various embodiments;

FIG. 11 illustrates an example computing environment, in accordance with at least one embodiment;

FIG. 12 illustrates another example computer system that may include optical interconnects, according to at least one embodiment;

FIG. 13A provides a top view of a 2.5D integrated co-packaged optics with a host ASIC on a substrate, in accordance with at least one embodiment;

FIG. 13B provides a cross-sectional view of an optical-electrical (OE) chiplet, in accordance with at least one embodiment;

FIG. 13C provides a cross-sectional view of the 2.5D integrated co-packaged optics illustrated in FIG. 13A;

FIG. 14 illustrates a dense 3D stacked module, in accordance with at least on embodiment; and

FIG. 15 illustrates incorporation of circuitry optimized for graphics and video processing with one or more parallel processors, in accordance with an example embodiment.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). Like numbers refer to like elements throughout. No element, act, or instruction used herein should be construed as critical or essential unless explicitly described as such.

As noted above, as bandwidth requirements increase, the number of high-speed channels running to and from computing resources (e.g., ASICs, CPUs, GPUs, DPUs, PPUs, QPUs, switches, and/or the like) increase along with the power consumption of the electronic modules. To increase the number of high-speed channels and accommodate the increased power consumption, the number of electrical connections provided by ball grid arrays of the electronic modules may be increased, which in turn increases the overall substrate size of the electronic modules. However, increasing the substrate size of an electronic module presents production challenges, such as increased substrate manufacturing yields, substrate warpage, and associated printed circuit board (PCB) assembly and solderability challenges. Therefore, technical challenges exist regarding how to increase the number of high-speed channels to and from a computing resource while maintaining a substrate size of the electronic module that prevents production challenges.

Various embodiments, provide technical solutions to these technical challenges. In various embodiments, an electronic module may be configured to place a computing resource in electrical communication with a system printed circuit board (PCB) and to facilitate communication with other computing resources. Some embodiments of the present disclosure are directed to a multi-chip module (MCM) configured to receive a centrally positioned main die that hosts one or more computing resources (e.g., ASICs, CPUs, GPUs, DPUs, PPUs, QPUs, switches, and/or the like) and a plurality of peripherally positioned MCM sockets configured to mechanically receive and electrically connect mezzanine packages to the main die. For example, the MCM substrate may comprise electrical traces and/or the like configured for communicating digital data between mezzanine packages coupled to respective MCM sockets and the main die.

The mezzanine packages include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate.

For mezzanine packages that require a power source, such as CPO packages, the mezzanine packages may be powered independently of the MCM. For example, the main portion of the mezzanine package that extends beyond the periphery of the MCM substrate may be in direct electrical communication with a system PCB to which the MCM substrate is coupled (e.g., via a ball grid array (BGA)). The mezzanine package may be electrically powered via the direct electrical communication with the PCB such that the electrical power for the mezzanine package need not be routed through the BGA.

The substrate of the MCM may have a width and length of 90 millimeters or less and may include a BGA to connect to a system PCB. For example, the substrate of the MCM may be sufficiently small as to prevent the noted production challenges. The MCM sockets connecting the mezzanine packages to the MCM substrate may include pin grid arrays having a pitch (e.g., 0.6 millimeters) that may be less than the pitch of the BGA connecting the MCM to the PCB (e.g., 1 millimeter). The MCM socket pins may include only high-speed signals and their respective ground isolations. For example, the MCM socket pins do not include power rails, in various embodiments. Other input/output pins and power planes may be fed into the mezzanine package by a different connector directly from the system PCB instead of through the MCM substrate. For example, a CPO package may include a power connection to the system PCB (e.g., via a cable), rather than to the MCM-substrate. By powering the mezzanine packages independently of the MCM substrate and the BGA providing electrical connections between the MCM substrate and the system PCB, the BGA used to electrically connect the MCM substrate and the system PCB may be maintained at a size that enables the MCM substrate to be sized so as to prevent the noted production challenges.

In some embodiments, the CPO package may be flipped such that its optical devices are disposed between the CPO substrate and the system PCB (e.g., the same side of the CPO substrate as the electrical connection to the MCM socket), thereby eliminating the need for traces running through the CPO substrate core and improving the signal integrity of the high-speed traces. Using such an MCM with preconfigured sockets and mezzanine packages also permits the MCM to support both CPO packages and CPC packages at the same time.

Thus, various embodiments provide technical improvements to the fields of interfacing with computing resources, electronic modules, electronic devices, and systems using such computing resources, such as datacenters and/or computing clusters.

### Example Electronic Devices Including an Electronic Module

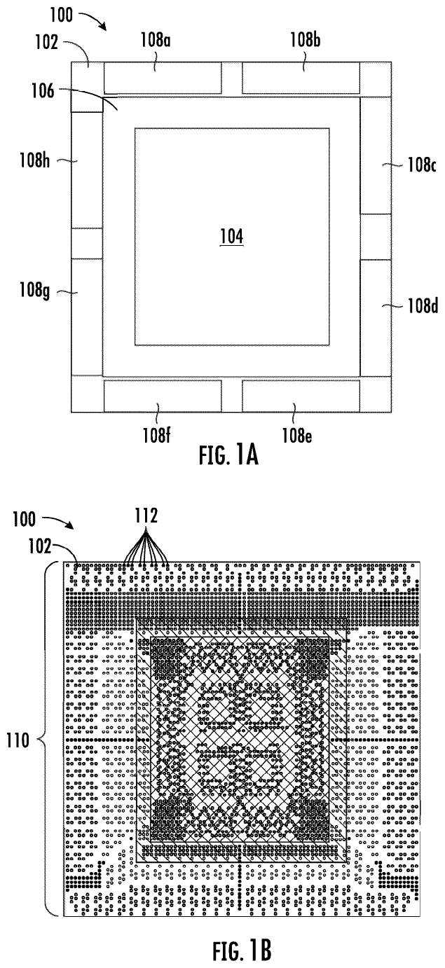

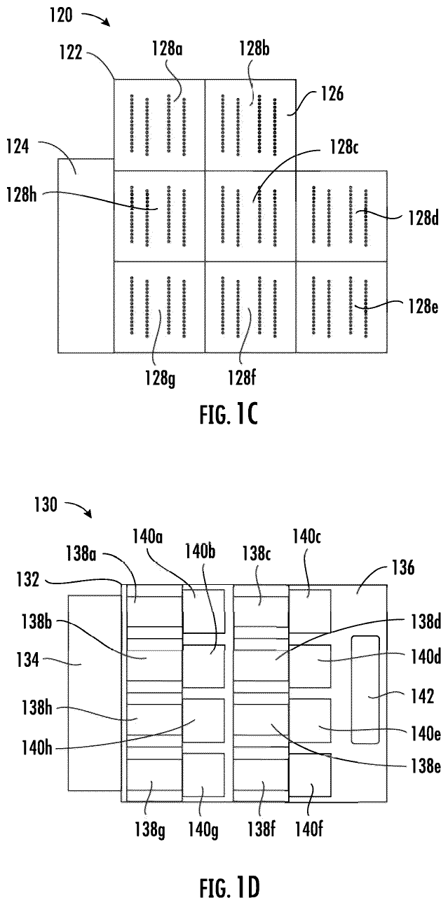

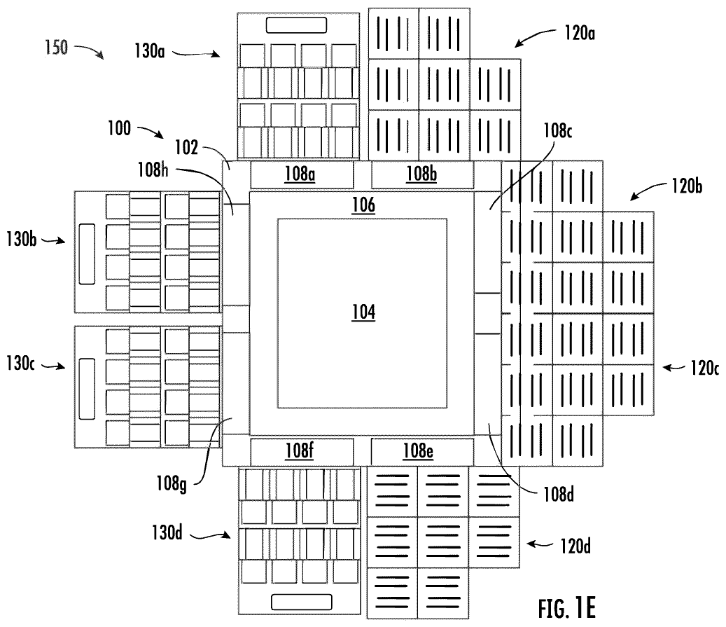

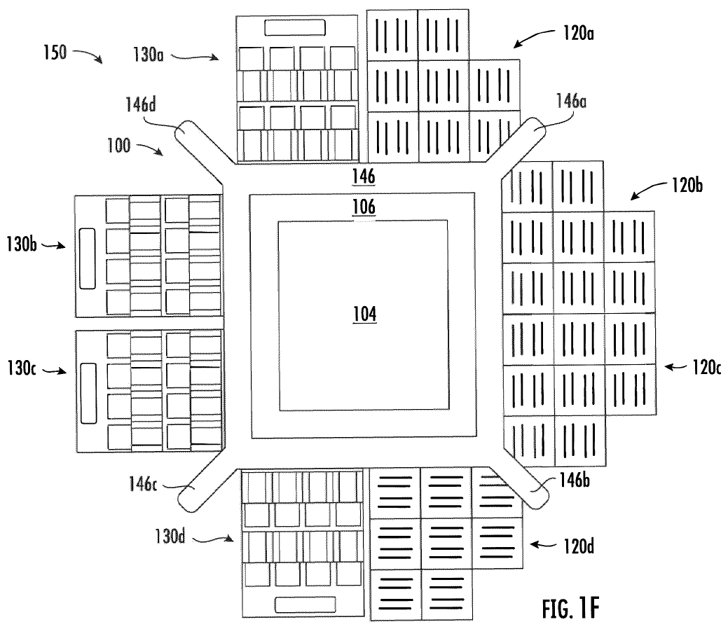

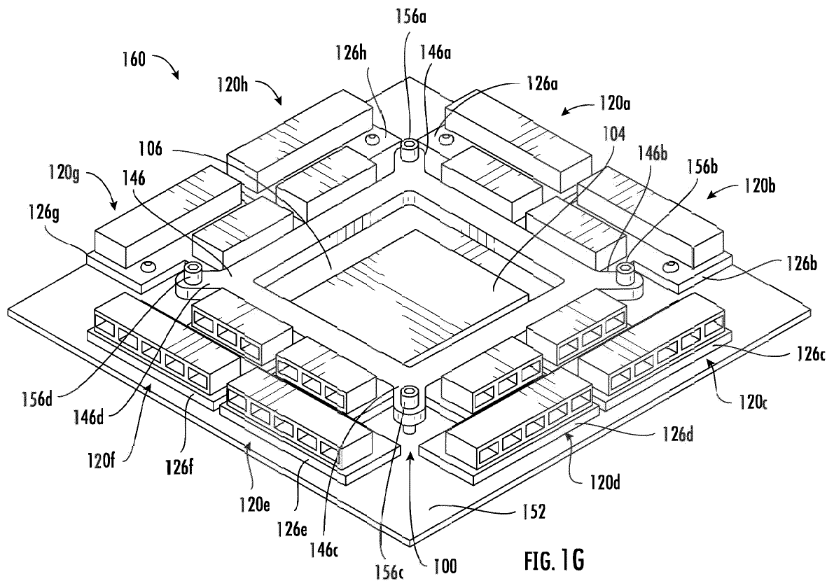

FIG. 1A is a top view of a multi-chip module (MCM) 100, in accordance with an embodiment of the invention, and FIG. 1B is a bottom view of the MCM of FIG. 1A. As shown in FIG. 1A, the MCM 100 may include an MCM substrate 102. The MCM substrate comprises a central portion configured to receive a main die. For example, in some embodiments, the MCM 100 includes a main die 104 positioned on a central portion of a surface of the MCM substrate 102. In some embodiments, the MCM substrate 102 may include electrical traces (e.g., through a thickness the MCM substrate 102), and the main die 104 may be in electrical communication with the electrical traces-when the main die is position in the central portion of the main die and electrically coupled to the MCM substrate 102. In various embodiments, the main die 104 hosts the computing resource (e.g., ASIC, CPU, GPU, DPU, PPU, QPU, switch, and/or the like).

As shown in FIG. 1A, the MCM 100 may include a component-free zone 106 (e.g., a component “keep out” zone) around the periphery of the central portion of the MCM substrate 102 that is configured to receive the main die 104. The component-free zone 106 may define a portion of the MCM substrate 102 on which no pads, sockets, vias, and/or other components are positioned (e.g., only traces may be permitted within the component-free zone 106). The component-free zone 106 may be established on the MCM substrate 102 to prevent electrical interference between components on the MCM substrate 102, to enable thermal dissipation (e.g., via a heatsink), and/or the like.

As shown in FIG. 1A, the MCM 100 may include a plurality of MCM sockets 108a-108h positioned on a peripheral portion of the surface of the MCM substrate 102 (e.g., outside of the component-free zone 106, between outer edges of the MCM substrate 102 and the central portion of the MCM substrate 102 that is configured to receive the main die 104 and/or the component-free zone 106, and/or the like). In some embodiments, each MCM socket of the plurality of MCM sockets 108a-108h may be in electrical communication with the electrical traces of the MCM substrate 102. As described herein with respect to FIGS. 1E-4B, each MCM socket of the plurality of MCM sockets 108a-108h may be configured to engage and support a mezzanine package substrate (e.g., of a CPO package or a CPC package) via a connector portion of the mezzanine package substrate such that a main portion of the mezzanine package substrate extends beyond the peripheral portion of the MCM substrate 102. For example, the mezzanine package substrate extends beyond the edge of the MCM substrate 102 when the mezzanine package is coupled into a respective MCM socket.

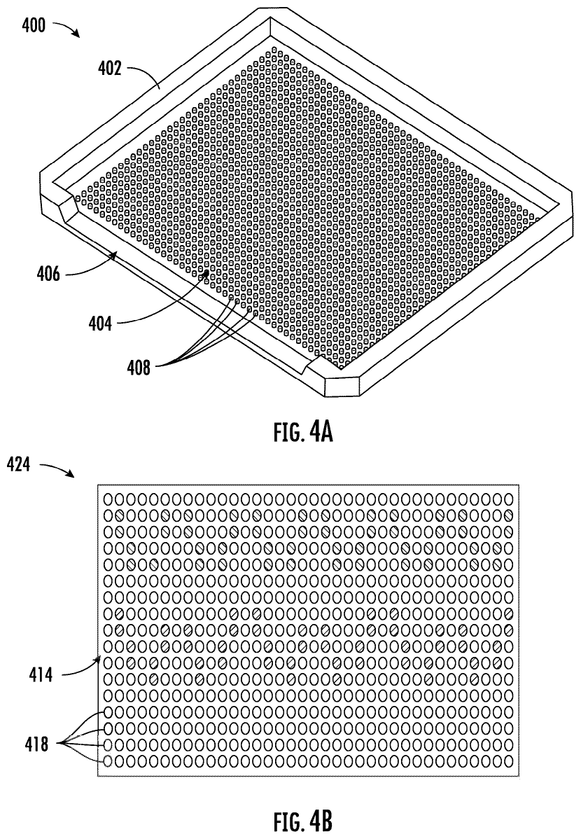

Furthermore, each MCM socket of the plurality of MCM sockets 108a-108h may be configured to electrically connect a mezzanine package substrate to the main die 104 via at least one of the electrical traces of the MCM substrate 102 for the communication of digital data, for example, therebetween. For example, the plurality of MCM sockets 108a-108h may be configured to electrically connect high speed signal pins, ground isolation pins, and/or other types of pins of the mezzanine packages to the MCM 100. In some embodiments, each MCM socket of the plurality of MCM sockets 108a-108h may be similar to a socket 400 as shown and described herein with respect to FIG. 4A.

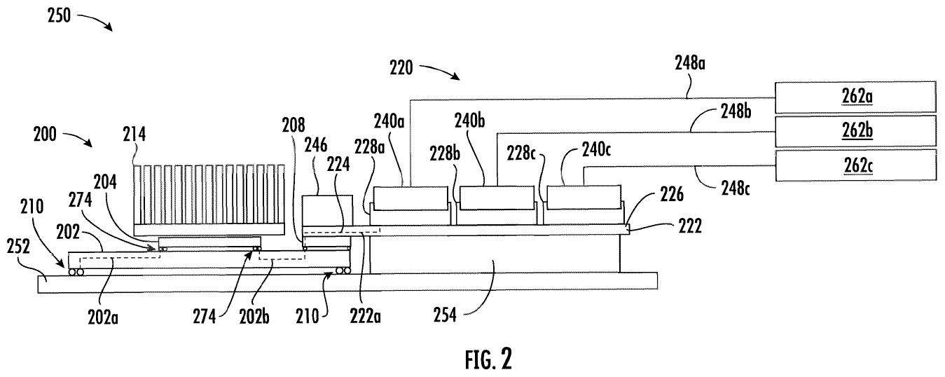

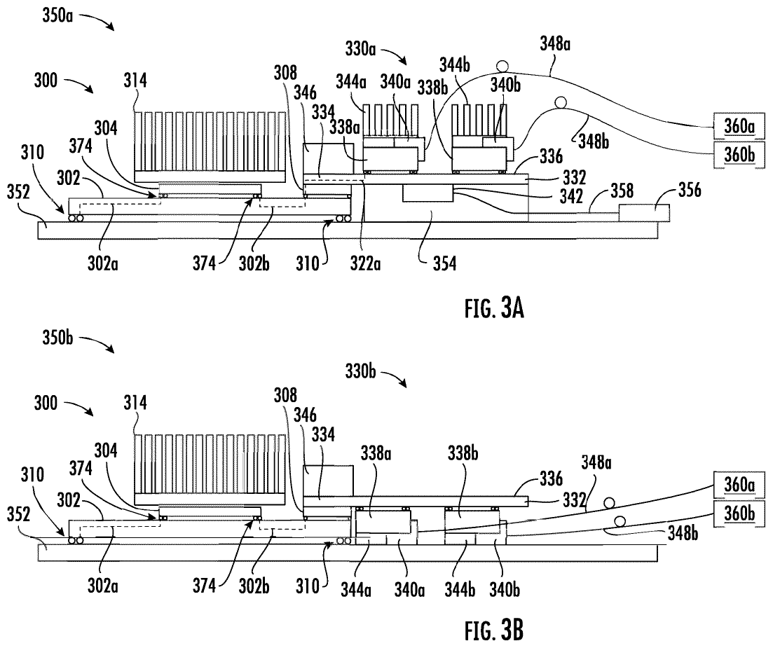

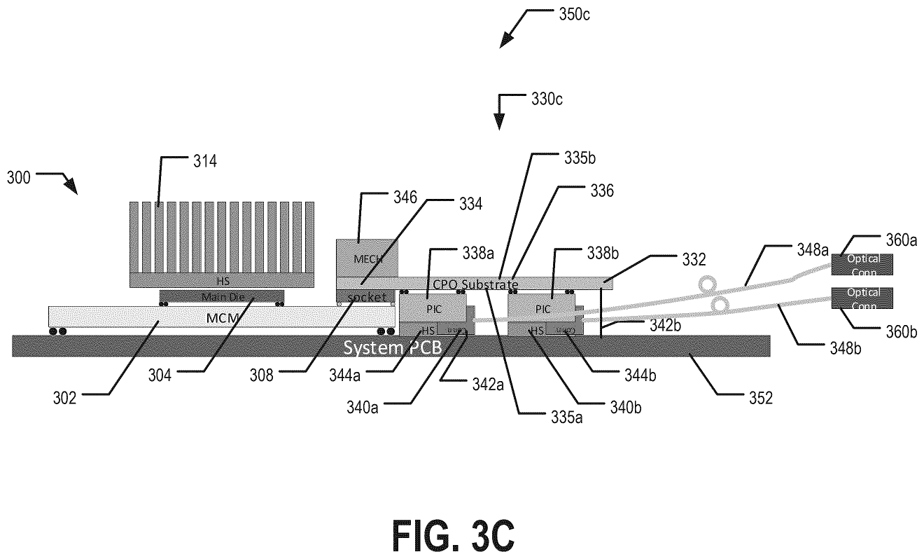

As shown in FIG. 1B, the MCM 100 may also include a ball grid array (BGA) 110 on another surface of the MCM substrate 102 opposite the surface configured to have the main die 104 positioned thereon and/or the plurality of MCM sockets 108a-108h is positioned. The BGA 110 may be configured to be connected to a system PCB (e.g., as shown and described herein with respect to FIGS. 2-3B). For example, the MCM 100 and/or the MCM substrate 102 may be electrically and mechanically connected to the system PCB by reflow soldering the BGA 110. As shown in FIG. 1B, the BGA 110 may include a plurality of solder balls 112 configured to provide electrical and mechanical connections to the MCM 100 and/or the MCM substrate 102 (e.g., providing electrical connections to the electrical traces of the MCM substrate 102).

As will be appreciated by those of ordinary skill in the art in view of this disclosure, FIGS. 1A and 1B depict a simplified and/or representative design for an MCM, in accordance with an embodiment of the invention. For example, the MCM 100 may include fewer MCM sockets (e.g., seven, six, five, four, three, two, or even one MCM socket), more MCM sockets (e.g., nine, ten, eleven, twelve, or more MCM sockets), differently sized, shaped, and/or positioned MCM sockets, while still engaging and supporting mezzanine packages extending beyond the peripheral portion of the MCM substrate 102. As another example, the MCM 100 may include one or more MCM sockets similar to the plurality of MCM sockets 108a-108h as well as one or more conventional MCM sockets configured to electrically connect to a CPO package or a CPC package that does not extend beyond the peripheral portion of the MCM substrate 102. As yet another example, the MCM substrate 102, the main die 104, and/or the component-free zone 106 may have a different size and/or shape as compared to that shown in FIGS. 1A and 1B.

FIG. 1C is a top view of a co-packaged copper (CPC) package 120, in accordance with an embodiment of the invention. In this regard, the CPC package 120 may be a type of mezzanine package referred to with respect to FIGS. 1A and 1B as being electrically connected to and supported by one of the MCM sockets 108a-108h of the MCM 100. As shown in FIG. 1C, the CPC package 120 may include a CPC substrate 122 (e.g., a mezzanine package substrate) including a connector portion 124 and a main portion 126. In some embodiments, the connector portion 124 may be configured to be engaged and supported by an MCM socket of an MCM (e.g., one of the MCM sockets 108a-108h of the MCM 100 of FIGS. 1A and 1B). For example, the connector portion 124 may be similar to a connector portion 424 shown and described herein with respect to FIG. 4B.

As shown in FIG. 1C, the CPC package 120 may also include devices 128a-128h (e.g., CPC sockets connected to radio-frequency (RF) copper cable connectors), and the main portion 126 may be configured to support the devices 128a-128h. In some embodiments, and as shown and described herein with respect to FIG. 1E, the CPC substrate 122 may be configured such that when the connector portion 124 is positioned within an MCM socket of an MCM, the main portion 126 extends beyond the peripheral portion of the MCM substrate (e.g., beyond the edge of the MCM substrate).

FIG. 1D is a top view of a co-packaged optics (CPO) package 130, in accordance with an embodiment of the invention. In this regard, the CPO package 130 may be a type of mezzanine package referred to with respect to FIGS. 1A and 1B as being electrically connected to and supported by one of the MCM sockets 108a-108h of the MCM 100. As shown in FIG. 1D, the CPO package may include a CPO substrate 132 (e.g., a mezzanine package substrate) including a connector portion 134 and a main portion 136. In some embodiments, the connector portion 134 may be configured to be engaged and supported by an MCM socket of an MCM (e.g., one of the MCM sockets 108a-108h of the MCM 100 of FIGS. 1A and 1B). For example, the connector portion 134 may be similar to a connector portion 424 shown and described herein with respect to FIG. 4B. In some embodiments, the CPO substrate 132 may be configured such that when the connector portion 134 is positioned within an MCM socket of an MCM, the main portion 136 extends beyond the peripheral portion of the MCM substrate (e.g., beyond the edge of the MCM substrate).

As shown in Figure ID, the CPO package 130 may also include optical devices 138a-138h, input/output connections 140a-140h, and a power connection 142. In various embodiments, each of the optical devices 138a-138h, input/output connections 140a-140h, and the power connection 142 are positioned on and/or supported by the main portion 136. In some embodiments, the optical devices 138a-138h may include photonic integrated circuits (PICs) and/or other optical communication devices (e.g., lasers, laser-modulators, laser drivers, photo detectors (PD), amplifiers e.g., transimpedance amplifiers (TIAs)), and/or the like). The input/output connections 140a-140h (e.g., optical connectors) may be configured to transmit input/output signals between a system PCB or other MCM and the CPO package 130 and/or the optical devices 138a-138h. The power connection 142 may be configured to receive power for the CPO package 130 (e.g., for the optical devices 138a-138h) from a system PCB. In some embodiments, and as shown and described herein with respect to FIG. 1E, the CPO substrate 132 may be configured such that when the connector portion 134 is positioned within an MCM socket of an MCM, the main portion 136 extends beyond the peripheral portion of the MCM substrate.

Thus, the plurality of mezzanine packages includes one or more CPC packages configured to support copper-based or electrical devices and one or more CPO packages configured to support optics-based or optical devices.

FIG. 1E is a top view of an electronic module 150 including the MCM 100 of FIG. 1A having a plurality of mezzanine packages (e.g., multiple CPC packages 120a-120d—and multiple CPO packages 130a-130d) coupled to the MCM sockets 108a-108h, in accordance with certain embodiments. As shown in FIG. 1E, in various embodiments, a CPC package 120 and a CPO package 130 are configured to have the same footprint (e.g., same dimensions) and/or to require the same amount of space of the MCM substrate and/or system PCB. For example, an MCM socket 108 may be configured to accommodate a CPC package 120 or a CPO package 130 interchangeably.

In some embodiments, each of the CPC packages 120a-120d may be similar to the CPC package 120 shown and described with respect to FIG. 1C. For example, each of the CPC packages 120a-120d may include a CPC substrate with a connector portion and a main portion as well as one or more devices positioned on the main portion similar to the CPC substrate 122, the connector portion 124, the main portion 126, and the devices 128a-128h of the CPC package 120 of FIG. 1C.

In some embodiments, each of the CPO packages 130a-130d may be similar to the CPO package 130 shown and described with respect to FIG. 1D. For example, each of the CPO packages 130a-130d may include a CPO substrate with a connector portion and a main portion as well as one or more optical devices, input/output connections, and a power connection positioned on the main portion respectively similar to the CPO substrate 132, the connector portion 134, the main portion 136, the optical devices 138a-138h, the input/output connections 140a-140h, and the power connection 142 of the CPO package 130 of FIG. 1D.

As will be appreciated by one of ordinary skill in the art in view of the present disclosure, the term mezzanine package may refer to a CPC package similar to the CPC package 120 of FIG. 1C or a CPO package similar to the CPO package 130 of FIG. 1D. Furthermore, the term mezzanine package substrate may refer to a CPC substrate similar to the CPC substrate 122 of FIG. 1C or a CPO substrate similar to the CPO substrate 132 of FIG. 1D. In this regard, a mezzanine package may include a mezzanine package substrate and one or more devices positioned on the mezzanine package substrate, where the mezzanine package substrate is configured to support and electrically connect the one or more devices to an MCM. The mezzanine package substrate may include a connector portion and a main portion, where the connector portion is configured to be engaged and supported by an MCM socket and the main portion is configured to extend beyond the peripheral portion of an MCM substrate. The main portion of the mezzanine package substrate may be configured to support the one or more devices. For example, each of the CPC packages 120a-120d and the CPO packages 130a-130d shown in FIG. 1E may be referred to as a mezzanine package, and their substrates may be referred to as mezzanine package substrates.

As shown in FIG. 1E, the electronic module 150 may include four CPC packages 120a-120d and four CPO packages 130a-130d, each engaged with and supported by one of the plurality of MCM sockets 108a-108h of the MCM 100. In this regard, a size and/or shape of the mezzanine package substrates of the CPC packages 120a-120d and the CPO packages 130a-130d may be configured such that the MCM 100 and the plurality of MCM sockets 108a-108h may accommodate a plurality of mezzanine packages. For example, the connector portions and the main portions of the mezzanine package substrates may be configured such that, when the connector portions are positioned on and/or within the plurality of MCM sockets 108a-108h as shown in FIG. 1E, the main portions of the mezzanine package substrates extend beyond the peripheral portion of the MCM substrate 102 and/or do not overlap with each other in a plane parallel to the MCM substrate 102.

In this way, the MCM 100 and the mezzanine packages may permit electronic module designers to increase the number of high-speed channels (e.g., via the MCM sockets instead of the ball grid array), while maintaining signal integrity, and accommodate increased power consumption of high-bandwidth designs without increasing a size of the MCM substrate 102. By avoiding increases to the size of the MCM substrate 102, the MCM 100 and the mezzanine packages may prevent the aforementioned production challenges, such as increased substrate manufacturing yields, substrate warpage, and associated PCB assembly and solderability challenges.

FIG. 1F is a top view of the electronic module 150 of FIG. 1E and an attachment member 146, in accordance with an embodiment of the invention. As shown in FIG. 1E, the attachment member 146 may include a plurality of attachment arms 146a-146d. In some embodiments, the attachment member 146 may be configured to be applied to the connector portions of the mezzanine packages so as to mechanically secure the mezzanine package substrates with respect to the MCM sockets 108a-108h. In some embodiments, and as shown in FIG. 1F, the attachment member 146 may be a contiguous element configured to simultaneously secure a plurality of connector portions of mezzanine package substrates in corresponding MCM sockets. The attachment member 146 is described in greater detail below and may include metal, plastic, and/or the like.

FIG. 1G is a perspective view of an electronic device 160 including the MCM 100 of FIG. 1A, multiple CPC packages 120a-120h, and the attachment member 146, in accordance with an embodiment of the invention. As shown in FIG. 1G, the electronic device 160 also includes a system PCB 152. As compared to the electronic module 150 of FIGS. 1E and 1F, the electronic device 160 of FIG. 1G includes CPC packages but not CPO packages. However, in some embodiments, the electronic device 160 may include combinations of CPC packages and CPO packages or only CPO packages.

Each of the CPC packages 120a-120h may be similar to the CPC package 120 shown and described with respect to FIG. 1C. For example, each of the CPC packages 120a-120h may include a CPC substrate 126a-126h with a connector portion and a main portion as well as one or more devices positioned on the main portion similar to the CPC substrate 122, the connector portion 124, the main portion 126, and the devices 128a-128h of the CPC package 120. As shown in FIG. 1G, the CPC substrates 126a-126h extend beyond the peripheral portion of the MCM substrate of the MCM 100.

As shown in FIG. 1F, the attachment member 146 may be configured to be attached to the system PCB 152 to which the MCM 100 is connected via fasteners 156a-156d (e.g., screws, bolts, pins, and/or the like). For example, and as shown in FIG. 1F, each of the attachment arms 146a-146d may be secured to the system PCB 152 by a respective fastener of the fasteners 156a-156d. In this regard, a fastener may include a narrow shank, which passes through a hole in an attachment arm, and a wider head which engages the attachment arm, such that when the shank is secured to the system PCB 152 the head of the fastener prevents movement of the attachment arm. In some embodiments, and as shown in FIG. 1F, the attachment member 146 may be a contiguous element configured to simultaneously secure a plurality of connector portions of mezzanine package substrates in corresponding MCM sockets. Additionally, or alternatively, the electronic device 160 may include multiple attachment members, where each attachment member secures a single mezzanine package substrate to an MCM socket, where each attachment member secures a subset of mezzanine package substrates (e.g., two, three, four, or more) to respective MCM sockets, and/or the like. For example, in some embodiments, each attachment member may be configured (e.g., sized and shaped) to secure one or more mezzanine package substrates installed in MCM sockets along a single side of the system PCB 152, such that multiple attachment members would be needed to secure mezzanine package substrates that are installed in MCM sockets of different sides of the system PCB (e.g., adjacent or opposite sides of the system PCB).

FIG. 2 is a cross-sectional view of an electronic device 250 including an electronic module that includes an MCM 200 and a CPC package 220, in accordance with an embodiment of the invention. As shown in FIG. 2, the electronic device 250 may include the MCM 200, the CPC package 220, an attachment member 246, RF cables 248a-248c, a system PCB 252, a support member 254, and electrical interfaces 262a-262c.

In some embodiments, the MCM 200 may be similar to the MCM 100 shown and described herein with respect to FIGS. 1A, 1B, and 1E. For example, and as shown in FIG. 2, the MCM 200 may include an MCM substrate 202, center portion configured to receive a main die 204, an MCM socket 208, and a BGA 210. The MCM substrate 202, the main die 204, the MCM socket 208, and the BGA 210 may be similar to the MCM substrate 102, the main die 104, one of the plurality of MCM sockets 108a-108h, and the BGA 110, respectively, of FIGS. 1A, 1B, and 1E.

As shown in FIG. 2, the MCM 200 may also include a heat sink 214 and a main die BGA 274. The heat sink 214 may provide thermal dissipation for the main die 204. The main die BGA 274 may be configured to mechanically and electrically connect the main die 204 to the MCM substrate 202. For example, the main die 204 may be placed into electrical communication with the electrical traces of the MCM substrate 202 via the main die BGA 274. In some embodiments, the main die 204 may be mechanically and electrically connected to the MCM substrate 202 using other structures, such as wire-bonding, and/or the like.

As also shown in FIG. 2, the MCM substrate 202 may include a trace 202a electrically connecting the main die 204 to the system PCB 252. In some embodiments, the MCM substrate 202 may include a plurality of traces similar to trace 202a for providing electrical connections between the main die 204 and/or the MCM socket 208 and the system PCB 252.

As shown in FIG. 2, the MCM substrate 202 may include a trace 202b electrically connecting the MCM socket 208 to the main die 204. In some embodiments, the MCM substrate 202 may include a plurality of traces similar to trace 202b for providing electrical connections between a plurality of MCM sockets and the main die 204 and/or the system PCB 252. In various embodiments, traces 202b are configured for communication of digital data between respective MCM sockets 208 and the main die 204.

In some embodiments, the CPC package 220 may be similar to the CPC package 120 shown and described herein with respect to FIGS. 1C, 1E, and 1F. For example, and as shown in FIG. 2, the CPC package 220 may include a CPC substrate 222 having a connector portion 224 and a main portion 226. The CPC substrate 222, the connector portion 224, and the main portion 226 may be similar to the CPC substrate 122, the connector portion 124, and the main portion 126, respectively, of FIGS. 1C, 1E, and 1F.

As shown in FIG. 2, the CPC package 220 may include CPC sockets 228a-228h and CPC connectors 240a-240c (e.g., RF cable connectors). In this regard, each of the CPC sockets 228a-228h may mechanically and electrically connect a respective CPC connector of the CPC connectors 240a-240c to the CPC substrate 222. Furthermore, each CPC socket and its respective CPC connector may be similar to the devices 128a-128f of the CPC package 120 of FIG. 1C.

As shown in FIG. 2, the CPC substrate 222 may include a trace 222a electrically connecting the CPC socket 228a to the MCM socket 208. Although not shown in FIG. 2, the CPC substrate 222 may include a plurality of traces similar to trace 222a for providing electrical connections between each of the CPC sockets 228a-228c and the MCM socket 208.

In some embodiments, each of the CPC connectors 240a-240c may be connected by a respective RF cable of the RF cables 248a-248c to a respective electrical interface of the electrical interfaces 262a-262c, as shown in FIG. 2. The electrical interfaces 262a-262c may include pluggable interfaces (e.g., small form-factor pluggable (SFP) interfaces) for providing electrical connection between the CPC package 220 and other components of the electronic device 250.

As shown in FIG. 2, the attachment member 246 may be configured to be applied to the connector portion 224 of the CPC substrate 222 so as to mechanically secure the CPC substrate 222 with respect to the MCM socket 208. Although not shown in FIG. 2, the attachment member 246 may be configured to be attached to the system PCB 252 (e.g., via one or more fasteners, screws, and/or the like). In some embodiments, the attachment member 246 may be similar to and/or a portion of the attachment member 146 shown and described herein with respect to FIGS. 1F and 1G. For example, the attachment member 246 may be a contiguous element configured to simultaneously secure a plurality of connector portions of mezzanine package substrates in corresponding MCM sockets.

As also shown in FIG. 2, the support member 254 may be configured to be positioned between the main portion 226 of the CPC substrate 222 and the system PCB 252 so as to support the main portion 226 of the CPC substrate 222 with respect to the system PCB 252. In some embodiments, the support member 254 may prevent strain and/or bending of the CPC substrate 222 or dislodgment of the CPC substrate 222 from the MCM socket 208. Additionally, or alternatively, the support member 254 may be configured to be positioned between multiple mezzanine package substrates and the system PCB 252 and simultaneously support the main portions of the mezzanine package substrates with respect to the system PCB 252. In some embodiments, the support member 254 may include metal, plastic, and/or the like as well as one or more elastomeric elements, such as cushions, to absorb vibrations.

FIG. 3A is a cross-sectional view of an electronic device 350a including an electronic module including an MCM 300 and a CPO package 330a, in accordance with an embodiment of the invention. As shown in FIG. 3A, the electronic device 350a may include the MCM 300, the CPO package 330a, a main die 304, an attachment member 346, optical cables 348a-348b, a system PCB 352, a support member 354, a power connection 356, a power cable 358, and optical interfaces 360a-360b.

In some embodiments, the MCM 300 may be similar to the MCM 100 shown and described herein with respect to FIGS. 1A, 1B, and 1E. For example, and as shown in FIG. 3A, the MCM 300 may include an MCM substrate 302, central portion configured to receive a main die 304, an MCM socket 308, and a BGA 310. The MCM substrate 302, the main die 304, the MCM socket 308, and the BGA 310 may be similar to the MCM substrate 102, the main die 104, one of the plurality of MCM sockets 108a-108h, and the BGA 110, respectively, of FIGS. 1A, 1B, and 1E.

As shown in FIG. 3A, the MCM 300 may also include a heat sink 314 and a main die BGA 374. The heat sink 314 may provide thermal dissipation for the main die 304. The main die BGA 374 may be configured to mechanically and electrically connect the main die 304 to the MCM substrate 302. For example, the main die 304 may be placed into electrical communication with the electrical traces of the MCM substrate 302 via the main die BGA 374. In some embodiments, the main die 304 may be mechanically and electrically connected to the MCM substrate 302 using other structures, such as wire-bonding, and/or the like.

As also shown in FIG. 3A, the MCM substrate 302 may include a trace 302a electrically connecting the main die 304 to the system PCB 352. In some embodiments, the MCM substrate 302 may include a plurality of traces similar to trace 302a for providing electrical connections between the main die 304 and/or the MCM socket 308 and the system PCB 352.

As shown in FIG. 3A, the MCM substrate 302 may include a trace 302b electrically connecting the MCM socket 308 to the main die 304. For example, the trace 302b may be configured for communicating digital data between a respective MCM socket 308 and the main die 304. In some embodiments, the MCM substrate 302 may include a plurality of traces similar to trace 302b for providing electrical connections between a plurality of MCM sockets and the main die 304 and/or the system PCB 352.

In some embodiments, the CPO package 330a may be similar to the CPO package 130 shown and described herein with respect to FIGS. 1D-1F. For example, and as shown in FIG. 3A, the CPO package 330a may include a CPO substrate 332 having a connector portion 334 and a main portion 336. The CPO substrate 332, the connector portion 334, and the main portion 336 may be similar to the CPO substrate 132, the connector portion 134, and the main portion 136, respectively, of FIGS. 1D-1F.

As shown in FIG. 3A, the CPO package 330a may include optical devices 338a-338b (e.g., PICs and/or other optical communication devices such as lasers, modulators, laser drivers, photo detectors, amplifiers, and/or the like) and optical connectors 340a-340b (e.g., optical cable connectors). In this regard, each of the optical devices 338a-338b may be optically and/or mechanically connected to a respective optical connector of the optical connectors 340a-340b. Furthermore, each of the optical devices 338a-338b may be similar to the optical devices 138a-138h of the CPO package 130 of FIG. 1D. Additionally, each of the optical connectors 340a-340b may be similar to the input/output connections 140a-140h of the CPO package 130 of FIG. 1D.

As also shown in FIG. 3A, the CPO package 330a may include heat sinks 344a-344b for the optical devices 338a-338b, respectively. Each of the heat sinks 344a-344b may provide thermal dissipation for a corresponding optical device of the optical devices 338a-338b.

As shown in FIG. 3A, the CPO substrate 332 may include a trace 332a electrically connecting the optical device 338a to the MCM socket 308. For example, the trace 332a is configured for communicating digital data between the optical device 338a and the MCM socket 308. Although not shown in FIG. 3A, the CPO substrate 332 may include a plurality of traces similar to trace 332a for providing electrical connections between each of the optical devices 338a-338b and the MCM socket 308.

In some embodiments, each of the optical connectors 340a-340b may be connected by a respective optical cable of the optical cables 348a-348b to a respective optical interface of the optical interfaces 360a-360b, as shown in FIG. 3A. The optical interfaces 360a-360b may include pluggable interfaces for providing optical connections between the CPO package 320 and other components of the electronic device 350a.

As shown in FIG. 3A, the CPO package 330a may include a power connection 342. The power connection 342 may be similar to the power connection 142 of the CPO package 130 of FIG. 1D. However, as shown in FIG. 3A, the power connection 342 may be disposed on an opposite side of the CPO substrate 332 from the optical devices 338a-338b, rather than on the same side of the CPO substrate 132 as the optical devices 138a-138h as shown in FIG. 1D. As shown in FIG. 3A, the power connection 342 may be connected to another power connection 356 on the system PCB 352 via the power cable 358. In this regard, the power connection 342 may be configured to receive power for the CPO package 330 (e.g., for powering the optical devices 338a-338b) from the power connection 356 on the system PCB 352 via the power cable 358. In other words, the optical devices 338a-338b may be powered via a direct electrical connection with the system PCB 352 and independently of the MCM substrate 302 and the BGA 310.

As shown in FIG. 3A, the attachment member 346 may be configured to be applied to the connector portion 334 of the CPO substrate 332 so as to mechanically secure the CPO substrate 332 with respect to the MCM socket 308. Although not shown in FIG. 3A, the attachment member 346 may be configured to be attached to the system PCB 352 (e.g., via one or more screws and/or the like). In some embodiments, the attachment member 346 may be similar to and/or a portion of the attachment member 146 shown and described herein with respect to FIGS. 1F and 1G. For example, the attachment member 346 may be a contiguous element configured to simultaneously secure a plurality of connector portions of mezzanine package substrates in corresponding MCM sockets.

As also shown in FIG. 3A, the support member 354 may be configured to be positioned between the main portion 336 of the CPO substrate 332 and the system PCB 352 so as to support the main portion 336 of the CPO substrate 332 with respect to the system PCB 352. In some embodiments, the support member 354 may prevent strain and/or bending of the CPO substrate 332 or dislodgment of the CPO substrate 332 from the MCM socket 308. Additionally, or alternatively, the support member 354 may be configured to be positioned between multiple mezzanine package substrates and the system PCB 352 and may serve to simultaneously support the main portions of the mezzanine package substrates with respect to the system PCB 352.

FIG. 3B is a cross-sectional view of an electronic device 350b including an electronic module including an MCM 300 and another CPO package 330b, in accordance with an embodiment of the invention. The electronic device 350b and the MCM 300 of FIG. 3B may be similar to the electronic device 350a and the MCM 300 of FIG. 3A. However, as shown in FIG. 3B, the optical devices 338a-338b (e.g., PICs and/or other optical communication devices such as lasers, modulators, laser drivers, photodetectors, amplifiers, and/or the like) and the optical connectors 340a-340b (e.g., optical cable connectors) are positioned on a surface of the main portion 336 of the CPO substrate 332 oriented toward the system PCB 352 when the connector portion 334 of the CPO substrate 332 is positioned in the MCM socket 308. For example, the CPO package 330b may include one or more optical devices 338a-338b configured for a flip-chipped implementation.

Stated differently, the optical devices 338a-338b and the optical connectors 340a-340b are positioned on the main portion 336 of the CPO substrate 332 between the CPO substrate 332 and the system PCB 352 when the connector portion 334 of the CPO substrate 332 is positioned in the MCM socket 308. Furthermore, the optical devices 338a-338b and the optical connectors 340a-340b are positioned on a same surface of the CPO substrate 332 as electrical connections between the CPO substrate 332 and the MCM socket 308.

By positioning the optical devices 338a-338b and the optical connectors 340a-340b in this manner, the CPO substrate 332 of CPO package 330b may not require traces through the CPO substrate 332 (e.g., similar to the trace 332a of CPO package 330a) for electrically connecting the optical devices 338a-338b to the MCM socket 308. Because the optical devices 338a-338b and the optical connectors 340a-340b are positioned on a same surface of the CPO substrate 332 as electrical connections between the CPO substrate 332 and the MCM socket 308, electrical communication between the optical devices 338a-338b and the MCM socket 308 may be accomplished via surface traces, wire bonding, and/or other means not requiring traces embedded within the CPO substrate 332. By omitting such embedded traces, the CPO package 330b may provide improved signal integrity of the electrical connections between the optical devices 338a-338b and the main die 304 and/or the system PCB 352.

Although not shown in FIG. 3B, the electronic device 350b may also include a support member similar to the support member 354 as shown and described with respect to FIG. 3A. Additionally, or alternatively, the optical devices 338a-338b, the optical connectors 340a-340b, and/or the heat sinks 344a-344b may be configured to be positioned between the main portion 336 of the CPO substrate 332 and the system PCB 352 and support the main portion 336 of the CPO substrate 332 with respect to the system PCB 352. For example, the optical devices 338a-338b, the optical connectors 340a-340b, and/or the heat sinks 344a-344b may be configured (e.g., sized and shaped) to interface with a surface of the system PCB 352, such that the optical devices, the optical connectors, and/or the heat sinks themselves serve as a “support member.” Optical devices 338a-338b, optical connectors 340a-340b, and/or heat sinks 344a-344b configured in such a manner may prevent strain and/or bending of the CPO substrate 332 or dislodgment of the CPO substrate 332 from the MCM socket 308.

FIG. 3C is a cross-sectional view of an electronic device 350c including an electronic module including an MCM 300 and another CPO package 330c, in accordance with an embodiment of the invention. The electronic device 350c and the MCM 300 of FIG. 3C may be similar to the electronic device 350b and the MCM 300 of FIG. 3B. However, as shown in FIG. 3C, the optical devices 338a-338b (e.g., PICs and/or other optical communication devices such as lasers, modulators, laser drivers, photodetectors, amplifiers, and/or the like) and the optical connectors 340a-340b (e.g., optical cable connectors) are flip-chip mounted on a surface of the main portion 336 of the CPO substrate 332 that is oriented toward the system PCB 352 when the connector portion 334 of the CPO substrate 332 is positioned in the MCM socket 308.

In certain embodiments, the CPO package 330c is configured as a flip-chip component such that a longitudinal axis of the first adiabatic transition profile of the CPO package and a longitudinal axis of the second adiabatic transition profile of the CPO package may be collinear. Said differently, the orientation of the CPO package 330c in such an embodiment does not require a mirror or other reflective surface to redirect optical signals between the electro-optical component and the receiving surface for coupling into a respective optical cable 348.

For example, the CPO substrate 332 comprises a first surface 335a and a second surface 335b. The first surface 335a faces the system PCB 352. In various embodiments, the contact array of the connector portion 334 is formed on the first surface 335a of the CPO substrate 332. The optical devices 338a-338b (e.g., PICs and/or other optical communication devices such as lasers, modulators, laser drivers, photodetectors, amplifiers, and/or the like) and the optical connectors 340a-340b (e.g., optical cable connectors) are also disposed on the first surface 335a of the CPO substrate 332. Stated differently, the optical devices 338a-338b and the optical connectors 340a-340b are positioned on the main portion 336 of the CPO substrate 332 between the CPO substrate 332 and the system PCB 352 when the connector portion 334 of the CPO substrate 332 is positioned in the MCM socket 308. Furthermore, the optical devices 338a-338b and the optical connectors 340a-340b are positioned on a same surface (e.g., the first surface 335a) of the CPO substrate 332 as electrical connections between the CPO substrate 332 and the MCM socket 308.

By positioning the optical devices 338a-338b and the optical connectors 340a-340b in this manner, the CPO substrate 332 of CPO package 330b may not require traces through the CPO substrate 332 (e.g., similar to the trace 332a of CPO package 330a) for electrically connecting the optical devices 338a-338b to the MCM socket 308. Because the optical devices 338a-338b and the optical connectors 340a-340b are positioned on a same surface of the CPO substrate 332 as electrical connections between the CPO substrate 332 and the MCM socket 308, electrical communication between the optical devices 338a-338b and the MCM socket 308 may be accomplished via surface traces, wire bonding, and/or other means not requiring traces embedded within the CPO substrate 332. By omitting such embedded traces, the CPO package 330b may provide improved signal integrity of the electrical connections between the optical devices 338a-338b and the main die 304 and/or the system PCB 352.

In some embodiments, the optical devices 338a-338b are powered via direct electrical connections with the system PCB 352 (e.g., not via the socket 308). In certain embodiments, each of the optical devices 338a-338b and the corresponding optical connector 340a-340b may be configured to be individually powered via a direct electrical connection with the system PCB 352. For example, a power connection 342a may be provided between the system PCB 352 and one or more of the optical devices 338a-338b, and/or optical connectors 340a-340b, in some embodiments. In some embodiments, the CPO package 330c is configured to be powered via a direct power connection 342b between the CPO substrate 332 and system PCB 352.

FIG. 4A is a perspective view of a socket 400 for an MCM, in accordance with an embodiment of the invention. For example, the socket 400 may be configured to receive a connector portion of a mezzanine package substrate of a mezzanine package (e.g., CPO package and/or CPC package). In an example embodiment, the socket 400 is configured to receive a CPO package or a CPC package, interchangeably. As shown in FIG. 4A, the socket 400 may include a socket frame 402 and a socket pin array 404. The socket frame 402 may define a peripheral access opening 406, and the socket pin array 404 may include a plurality of pins 408.

In some embodiments, the socket 400 may be one or more of the MCM sockets 108a-108h shown and described herein with respect to FIGS. 1A and 1E. For example, the peripheral access opening 406 may be configured to receive a connector portion of a mezzanine package substrate and/or allow a main portion of the mezzanine package substrate to extend beyond an edge of the socket 400 (e.g., through the peripheral access opening 406). As another example, the socket pin array 404 and/or the plurality of pins 408 may be configured to engage a surface of an MCM substrate and electrically connect a mezzanine package substrate to a main die on the MCM substrate (e.g., via one or more electrical traces of the MCM substrate). For example, the socket pin array 404 and/or the plurality of pins 408 may be configured to engage a bottom surface of a connector portion of a mezzanine package including a corresponding contact array and/or a corresponding plurality of contacts (e.g., similar to the connector portion, contact array, and/or plurality of contacts shown and described herein with respect to FIG. 4B). For example, the socket pin array 404 and/or the plurality of pins 408 are configured for communicating digital data between a mezzanine package and the MCM substrate.

In some embodiments, a pitch of the socket pin array 404 (e.g., a minimum distance between adjacent pins of the plurality of pins 408) may be less than a pitch of a BGA of the MCM on which it is positioned. For example, in an embodiment in which the socket 400 is one of the MCM sockets 108a-108h of the MCM 100, the pitch of the socket pin array 404 may be less than a pitch of the BGA 110 (e.g., a minimum distance between adjacent solder balls 112 of the BGA 110). Such embodiments may require less surface area on the MCM substrate 102 for the socket 400 to establish electrical connections between the mezzanine package and the MCM 100 as compared to conventional sockets.

FIG. 4B is a bottom view of a connector portion 424 of a mezzanine package substrate, in accordance with an embodiment of the invention. As shown in FIG. 4B, the connector portion 424 may include a contact array 414 including a plurality of contacts 418. Each contact of the plurality of contacts 418 may include a surface (e.g., a metallic surface) configured to engage a corresponding pin of a socket pin array of an MCM socket (e.g., a pin of the socket pin array 404 of the socket 400 of FIG. 4A). The mezzanine package including the connector portion 424 may be a CPO package or a CPC package. For example, a CPO package and a CPC package have the same footprint, in various embodiments.

In some embodiments, the connector portion 424 may be the connector portion 124 of the CPC substrate 122 of FIG. 1C, the connector portion 134 of the CPO substrate 132 of FIG. 1D, and/or a connector portion of any other mezzanine package substrate described herein. In this regard, the bottom view of FIG. 4B shows the surface of the connector portion 424 that interfaces with and engages an MCM socket on an MCM and electrically connects the MCM socket to the mezzanine package substrate. For example, the contact array 414 and/or the plurality of contacts 418 may be configured to engage an upper surface of a socket including a socket pin array and/or a plurality of pins (e.g., similar to the socket 400, socket pin array 404, and/or plurality of pins 408 shown and described herein with respect to FIG. 4A). As another example, the connector portion 424 may be configured (e.g., by having a shape and/or a size) to fit within a peripheral access opening defined by a frame of a socket (e.g., similar to the peripheral access opening 406 defined by the socket frame 402 of the socket 400 shown and described herein with respect to FIG. 4A).

### Example Method of Fabricating an Electronic Device Including an Electronic Module

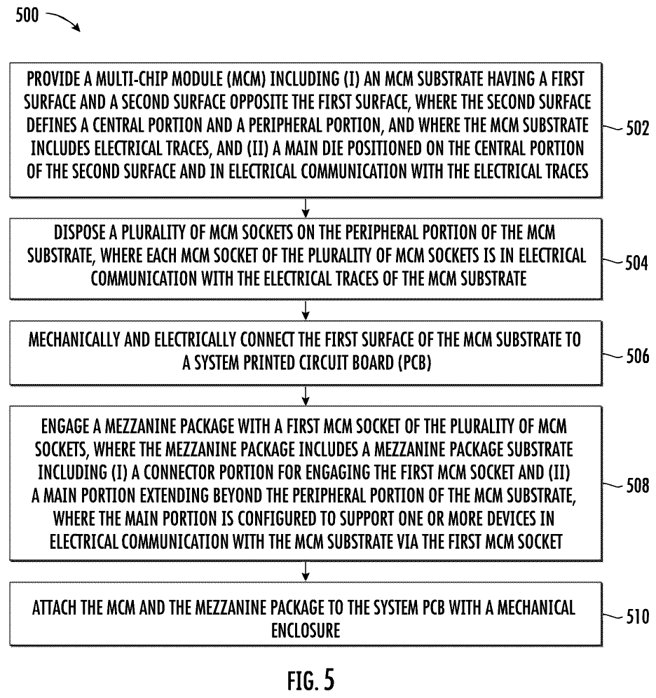

FIG. 5 is a flowchart illustrating a method 500 of assembling an electronic device, in accordance with an embodiment of the invention. In some embodiments, the electronic device may be similar to one or more of the electronic modules and/or electronic devices described herein, such as the electronic module 150 of FIGS. 1E and 1F, the electronic device 250 of FIG. 2, the electronic device 350a of FIG. 3A, and/or the electronic device 350b of FIG. 3B.

As shown in block 502, the method 500 may include providing a multi-chip module (MCM). The MCM may include (i) an MCM substrate having a first surface and a second surface opposite the first surface, where the second surface defines a central portion and a peripheral portion and the MCM substrate includes electrical traces, and (ii) a main die may be positioned on the central portion of the second surface and in electrical communication with the electrical traces. For example, the MCM may be similar to the MCM 100 of FIGS. 1A, 1B, 1E, and 1F, the MCM 200 of FIG. 2, and/or the MCM 300 of FIGS. 3A and 3B.

As shown in block 504, the method 500 may include disposing a plurality of MCM sockets on the peripheral portion of the MCM substrate, where each MCM socket of the plurality of MCM sockets is in electrical communication with the electrical traces of the MCM substrate. For example, the plurality of MCM sockets may be similar to the plurality of MCM sockets 108a-108h of FIGS. 1A, 1E, and 1F, the MCM socket 208 of FIG. 2, the MCM socket 308 of FIGS. 3A and 3B, and/or the socket 400 of FIG. 4A.

As shown in block 506, the method 500 may include mechanically and electrically connecting the first surface of the MCM substrate to a system printed circuit board (PCB). For example, the system PCB may be similar to the system PCB 252 of FIG. 2 and/or the system PCB 352 of FIGS. 3A and 3B. In some embodiments, mechanically and electrically connecting the first surface of the MCM to the system PCB may include reflow soldering a ball grid array (BGA) on the first surface of the MCM (e.g., similar to the BGA 110 of FIG. 1B, the BGA 210 of FIG. 2, and/or the BGA 310 of FIGS. 3A and 3B).

As shown in block 508, the method 500 may include engaging a mezzanine package with a first MCM socket of the plurality of MCM sockets. The mezzanine package may include a mezzanine package substrate that includes (i) a connector portion for engaging the first MCM socket and (ii) a main portion extending beyond the peripheral portion of the MCM substrate, where the main portion is configured to support one or more devices in electrical communication with the MCM substrate via the first MCM socket. For example, the mezzanine package may be similar to the CPC package 120 of FIG. 1C, the CPC packages 120a, 120b, 120c, and 120d of FIGS. 1E and 1F, the CPC package 220 of FIG. 2, the CPO package 130 of FIG. 1D, the CPO packages 130a, 130b, 130c, and 130d of FIGS. 1E and 1F, the CPO package 330a of FIG. 3A, and/or the CPO package 330b of FIG. 3B.

In some embodiments, engaging the mezzanine package with the first MCM socket may include applying an attachment member to the connector portion of the mezzanine package substrate and/or securing the attachment member to the system PCB, where the connector portion of the mezzanine package substrate is disposed between the attachment member and the first MCM socket. For example, the attachment member may be similar to the attachment member 146 of FIGS. 1F and 1G, the attachment member 246 of FIG. 2, and/or the attachment member 346 of FIGS. 3A and 3B. In some embodiments, securing the attachment member to the system PCB may include securing attachment arms of the attachment member (e.g., similar to the attachment arms 146a-146d of FIG. 1F) to the system PCB.

In some embodiments, the mezzanine package is a first mezzanine package, and the mezzanine package substrate is a first mezzanine package substrate. In such embodiments, the method 500 may include engaging a second mezzanine package with a second MCM socket of the plurality of MCM sockets, where the second mezzanine package includes a second mezzanine package substrate that includes (i) a connector portion for engaging the second MCM socket and (ii) a main portion extending beyond the peripheral portion of the MCM substrate, where the main portion is configured to support one or more devices in electrical communication with the MCM substrate via the second MCM socket. For example, the first mezzanine package may be a CPC package, and the second mezzanine package may be a CPO package.

Additionally, or alternatively, the method 500 may include engaging additional mezzanine packages with the other MCM sockets of the plurality of MCM sockets such that each MCM socket of the plurality of MCM sockets is engaged by a respective mezzanine package. The mezzanine packages may include only CPC packages, only CPO packages, or combinations of any number of CPC packages with any number of CPO packages as permitted by a number of MCM sockets on the MCM substrate.

As shown in block 510, the method 500 may include attaching the MCM and the mezzanine package to the system PCB with a mechanical enclosure. For example, the method 500 may include using an attachment member (e.g., similar to the attachment member 146, the attachment member 246, the attachment member 346, and/or the like) and/or a support member (e.g., similar to the support member 254, the support member 354, and/or the like) to attach the MCM and the mezzanine package to the system PCB.

Method 500 may include additional embodiments, such as any single embodiment or any combination of embodiments described herein. Although FIG. 5 shows example blocks of method 500, in some embodiments, method 500 may include additional blocks, fewer blocks, different blocks, or differently arranged blocks than those depicted in FIG. 5. Additionally, or alternatively, two or more of the blocks of method 500 may be performed in parallel.

For example, in some embodiments, an electronic module is fabricated by fabricating and/or providing an MCM substrate having a plurality of sockets and engaging a plurality of mezzanine packages (e.g., at least one CPO package and at least one CPC package) with respective sockets of the plurality of sockets. An electronic device including the electronic module may then be fabricated by securing the main die into the central portion of the MCM substrate and attaching the MCM substrate and mezzanine packages to the system PCB.

As will be appreciated by one of ordinary skill in the art in view of this disclosure, the present invention may include and/or be embodied as an apparatus (including, for example, a system, a machine, a device, and/or the like), as a method (including, for example, a manufacturing method, a robot-implemented process, and/or the like), or as any combination of the foregoing.

### Example Datacenter Including Electronic Modules

In various embodiments, a system includes multiple computing resources that may be in communication with one another via respective electronic modules. For example, a computing resource may be positioned at the central portion of an MCM substrate of an electronic module such that the computing resource and a plurality of mezzanine packages secured in sockets of the MCM substrate may communicate digital data to one another via the MCM substrate (e.g., via traces of the MCM substrate). The electronic module may be secured to a system PCB. The computing resource may communicate with one or more other computing resources via the system PCB, via cabled connections facilitated by CPC packages of the plurality of mezzanine packages, and/or via optical connections facilitated by CPO packages of the plurality of mezzanine packages. Such systems may be or may be included in datacenters, computing clusters, and/or other environments requiring communication between computing resources.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

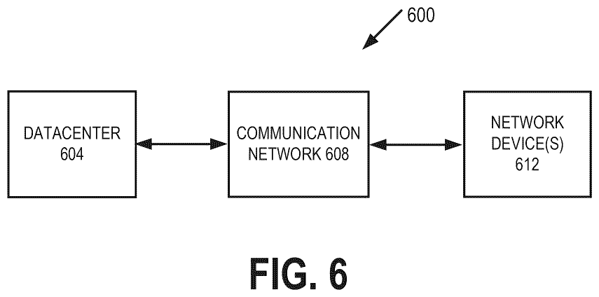

FIG. 6 illustrates a system 600 according to at least one example embodiment. The system 600 includes a datacenter 604, a communication network 608, and one or more network devices 612. One or more of the datacenter 604, communication network 608, and/or the one or more network devices 612 may include an electronic module and/or electronic device of an example embodiment. In at least one example embodiment, the datacenter 604 corresponds to a collection of network devices, such as network switches (e.g., Ethernet switches) connected with a collection of servers or compute nodes. The datacenter 604 may adhere to a networking topology (e.g., a hierarchal networking topology), such as a fat tree topology, a Slim Fly topology, a Dragonfly topology, and/or the like. The datacenter 604 routes traffic amongst the network switches and servers therein, and at least one layer of the topology in the datacenter 604 is coupled to the communication network 608 to allow networking traffic to flow between the datacenter 604 and the network device(s) 612.

Examples of the communication network 608 that may be used to connect the datacenter 604 and the network device(s) 612 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 612 may include switch, router, or Network Interface Controller (NIC), interconnect using ports, one or more of Personal Computer (PC), a laptop, a tablet, a smartphone, a server, a collection of servers, and/or any suitable computing device for sending and receiving signals over the communication network 608. In at least one example embodiment, the one or more network devices 612 correspond to another datacenter, similar to or the same as datacenter 604.

As noted above, the datacenter 604 and/or the network device(s) 612 may include computing resources such as storage devices and/or processing circuitry for carrying out computing tasks, for example, tasks associated with controlling the flow of data internally and/or over the communication network 608. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), a Field Programmable Gate Array (FPGA), a network interface controller (NIC), an ASIC, combinations thereof, and the like. The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 604 and network device(s) 612 may include one or more communication interfaces for facilitating wired and/or wireless communication between one another and other unillustrated elements of the system 600.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links or optical interconnects using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

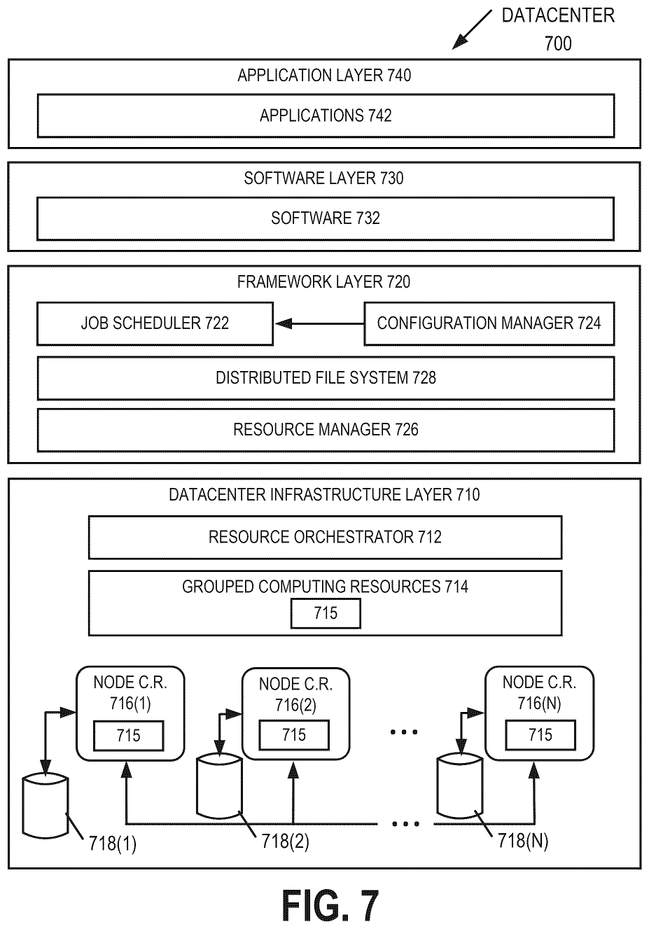

FIG. 7 illustrates an example datacenter 700, in which at least one embodiment may be used. In at least one embodiment, datacenter 700 includes a datacenter infrastructure layer 710, a framework layer 720, a software layer 730, and an application layer 740.

In at least one embodiment, as shown in FIG. 7, datacenter infrastructure layer 710 may include a resource orchestrator 712, grouped computing resources 714, and node computing resources (“node C.R.s”) 716(1)-716(N), where “N” represents a positive integer (which may be a different integer “N” than used in other figures). In at least one embodiment, node C.R.s 716(1)-716(N) may include, but are not limited to, any number of central processing units (“CPUs”) or other processors (including accelerators, field programmable gate arrays (FPGAs), graphics processors, etc.), memory storage devices 718(1)-718(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 716(1)-716(N) may be a server having one or more of above-mentioned computing resources. For example, various computing resources may be in communication with one another via communication channels provided via mezzanine packages of respective electronic modules to which respective computing resources are secured (e.g., as a main die positioned in a central portion of an MCM substrate of the respective electronic module).

In at least one embodiment, grouped computing resources 714 may include separate groupings of node C.R.s housed within one or more racks (not shown), or many racks housed in datacenters at various geographical locations (also not shown). In at least one embodiment, separate groupings of node C.R.s within grouped computing resources 714 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R.s 716(1)-716(N) and/or grouped computing resources 714. In at least one embodiment, resource orchestrator 77 may include a software design infrastructure (“SDI”) management entity for datacenter 700. In at least one embodiment, resource orchestrator 77 may include hardware, software or some combination thereof.

In at least one embodiment, as shown in FIG. 7, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may utilize distributed file system 728 for large-scale data processing (e.g., “big data”). In at least one embodiment, job scheduler 722 may include a Spark driver to facilitate scheduling of workloads supported by various layers of datacenter 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resources 714 at datacenter infrastructure layer 710. In at least one embodiment, resource manager 726 may coordinate with resource orchestrator 77 to manage these mapped or allocated computing resources.

In at least one embodiment, software 732 included in software layer 730 may include software used by at least portions of node C.R.s 716(1)-716(N), grouped computing resources 714, and/or distributed file system 728 of framework layer 720. In at least one embodiment, one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 728 of framework layer 720. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a datacenter operator of datacenter 700 from making possibly bad configuration decisions and possibly avoiding underutilized and/or poor performing portions of a datacenter.

In at least one embodiment, datacenter 700 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 700. In at least one embodiment, trained machine learning models corresponding to one or more neural networks may be used to infer or predict information using resources described above with respect to datacenter 700 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 715 are used to perform inferencing and/or training operations associated with one or more embodiments. In at least one embodiment, inference, and/or training logic 715 may be used in system FIG. 7 for inferencing or predicting operations based, at least in part, on weight parameters calculated using neural network training operations, neural network functions and/or architectures, or neural network use cases described herein.

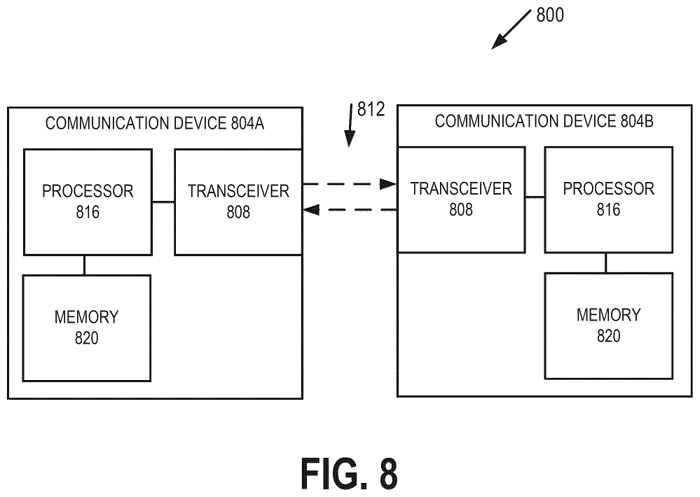

FIG. 8 illustrates a system 800 including a first communication device 804A and a second communication device 804B. Illustratively, but without limitation, the communication devices 804 (e.g., 804A, 804B) may correspond to network devices (e.g., network devices 612). As such, the communication devices 804 may correspond to any type of device that becomes part of or is connected with a communication network (e.g., communication network 608). Examples of suitable devices that may act or operate like a communication device 804 as described herein include, without limitation, one or more of a Personal Computer (PC), a laptop, a tablet, a smartphone, a server, a collection of servers, a networking card, an edge router, a switch, Network Interface Controller, a Top of Rack (ToR) switch, a server blade, or the like. The communication device 804 may include a transceiver 808, a processor 816, and memory 820. The transceiver 808 may include hardware that enables communications over the communication channel 812 whereas the processor 816 and memory 820 may include components that enable the communication device 804 to provide a desired functionality or perform certain functions.

The communication channel 812 may traverse a datacenter or any type of communication network (whether trusted or untrusted). Examples of a communication network that may be used to connect communication devices 804 and support the communication channel 812 include, without limitation, an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific, but non-limiting example, the communication network enables data transmission between the communication devices 804 using optical signals. In this case, the communication devices 804 and the communication network may include waveguides (e.g., optical fibers) that carry the optical signals.

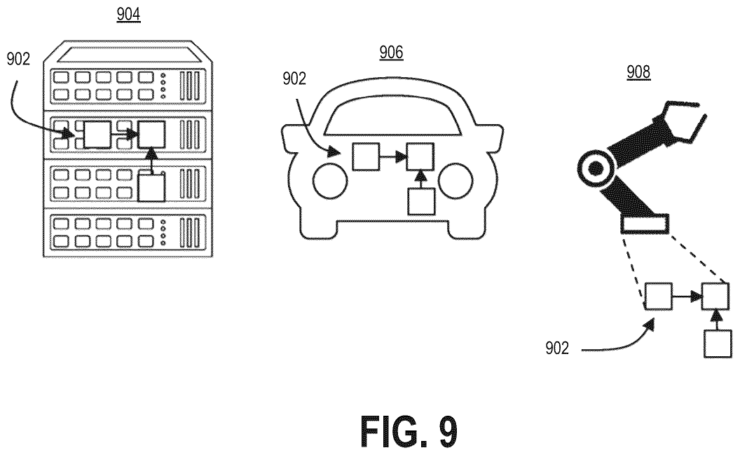

FIG. 9 depicts some exemplary scenarios for use of an electronic module 902 in accordance with some embodiments. An electronic module 902 configured to provide high speed communication channels for communicating with a computing resource may be utilized in a computing system 904 (e.g., in a server farm, or within a server computer system), a vehicle 906 (e.g., a car, truck, train, or airplane), and a robot 908 (or among robots in a factory), to name just a few examples.

### Example System Use Case

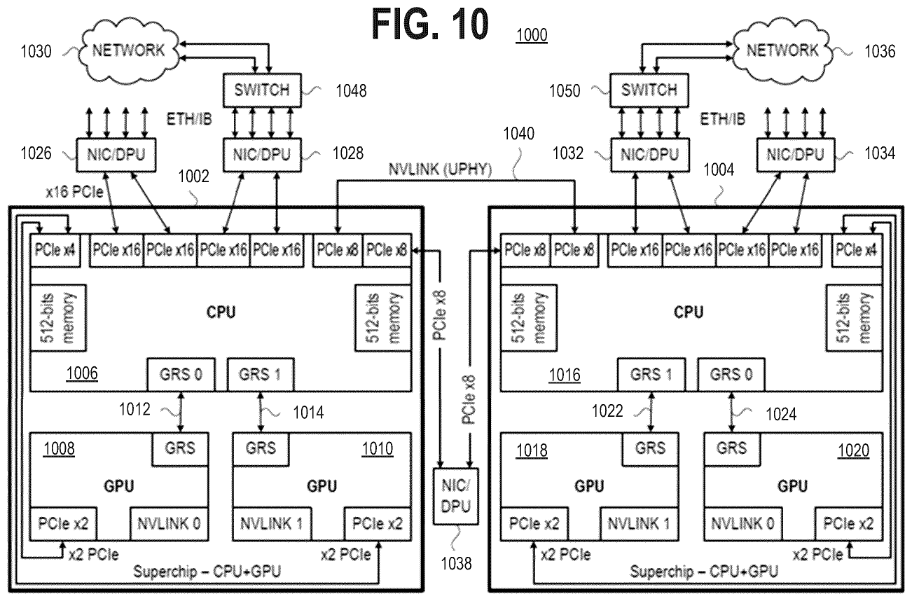

FIG. 10 is a block diagram that schematically illustrates a computing system 1000, e.g., a data center or a High-Performance Computing (HPC) cluster, in accordance with an embodiment that is described herein. System 1000 comprises a plurality of subsystems, e.g., multiple processing devices coupled to each other, multiple network devices, and multiple networks, according to at least one embodiment. Computing system 1000 is designed with multiple integrated circuits (referred to as processing devices), where each integrated circuit can include one or more CPUs and GPUs, forming a powerful and flexible architecture. In various embodiments, communication between respective processing devices may be facilitated by high speed communication channels provided via mezzanine packages of respective electronic modules to which respective processing devices are secured (e.g., as a main die positioned in a central portion of an MCM substrate of the respective electronic module).

The various processing devices are interconnected via an NVLink or other high-speed interconnect, enabling high-speed communication between the subsystems, and are also connected through a NIC or DPU to ensure efficient data transfer across computing system 1000 and to one or more external networks 1030, 1036. In the present example, system 1000 comprises a packet switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1000 can include one or more CPUs and one or more GPUs.

FIG. 10 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1008, and a GPU 1010. In an example embodiment, each of the CPU 1006, and GPUs 1008, 1010 are in electronic communication with a respective electronic module (e.g., positioned in a central portion of a respective MCM substrate of the electronic module). CPU 1006 can be coupled to GPU 1008 via a die-to-die (D2D) or chip-to-chip (C2C) interconnect 1012, such as a Ground-Referenced Signaling interconnect (GRS interconnect), facilitated via respective electronic modules. CPU 1006 can be coupled to GPU 1010 via a D2D or C2C interconnect 1014. CPU 1006 can also couple to GPU 1008 and GPU 1010 via PCIe interconnects facilitated via respective electronic modules.

CPU 1006 can be coupled to one or more NICs or DPUs, which are coupled to one or more networks. For example, as illustrated in FIG. 10, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1000 also includes a processing device 1004 with a multi-GPU architecture. In particular, processing device 1004 includes multiple subsystems including a CPU 1016, a GPU 1018, and a GPU 1020. In an example embodiment, each of the CPU 1006, and GPUs 1008, 1010 are in electronic communication with a respective electronic module (e.g., positioned in a central portion of a respective MCM substrate of the electronic module). CPU 1016 can be coupled to GPU 1018 via an D2D or C2C interconnect 1022 facilitated via respective electronic modules. CPU 1016 can be coupled to GPU 1020 via a D2D or C2C interconnect 1024 facilitated via respective electronic modules. CPU 1016 can also couple to GPU 1018 and GPU 1020 via PCIe interconnects facilitated via respective electronic modules. CPU 1016 can be coupled to one or more NICs or DPUs, which are coupled to one or more networks. For example, as illustrated in FIG. 10, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1002 and processing device 1004 can communication with each other via a NIC/DPU 1038, such as over PCIe interconnects. Processing device 1002 and processing device 1004 can also communicate with each other over a high-bandwidth communication interconnects 1040, such as an NVLink interconnect or other high-speed interconnects. The packet switches in FIG. 10 may comprise, for example, Nvidia Quantum-2 switches. The NICs/DPUs in the figure may comprise, for example, Nvidia Bluefield DPUs.

In various embodiments, one or more of the interconnects 1012, 1014, 1022, 1024 may be optical interconnects disclosed herein. Additionally, in various embodiments, switches 1048, 1050 may be in communication with NIC/DPU 1028, 1032, respectively, via one or more optical interconnects disclosed herein. In some embodiments, NIC/DPU 1026, 1034 may be in communication with one or more additional elements via optical interconnects disclosed herein. For example, various elements of the computing system 1000 may be in communication with one another via one or more optical interconnects disclosed herein.

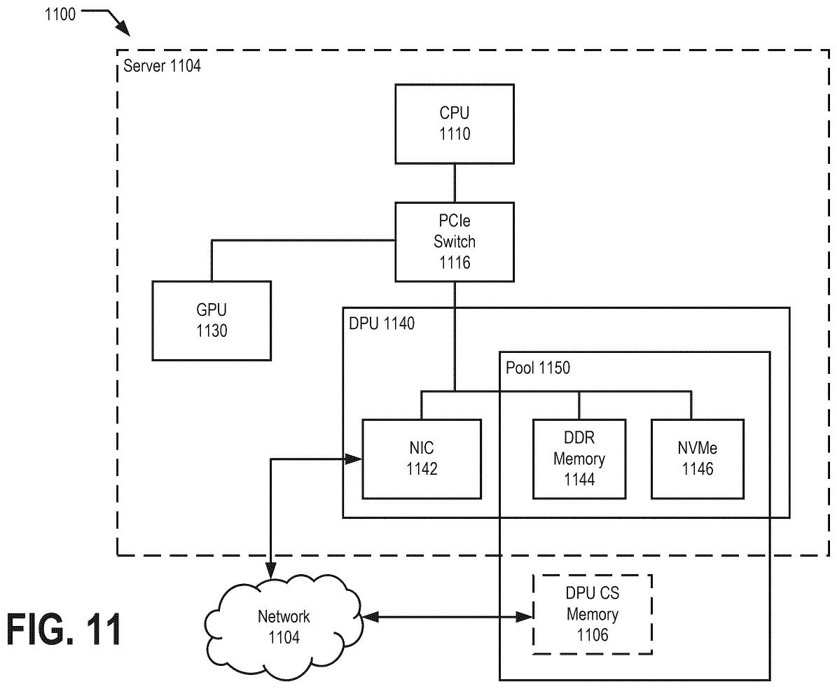

FIG. 11 illustrates an example computing environment 1100 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1100 may include a server 1102 which may be used to perform high performance computing (HPC) workloads, such as AI training or machine learning model training. In an embodiment, the server 1102 may be an application instance or a compute node. The server 1102 may include a CPU 1110 associated with a switch 1120, such as a peripheral component interconnect express (PCIe) switch, which may control at least some data transmission over communication paths interconnecting various components. For example, the CPU may be provided as a main die positioned in a central portion of an MCM substrate of an electronic module such that communication paths to interconnecting components may be provided via mezzanine packages of the electronic module. In an embodiment, the CPU 1110 may include a root complex processor.

The PCIe switch 1120 may also be associated with a GPU 1130 and a DPU 1140, and may transmit data between at least some of the CPU 1110, the GPU 1130, the DPU 1140, and other components (e.g., via one or more optical interconnects disclosed herein). In an embodiment, the PCIe switch 1120 may be associated with more than one GPU or more than one DPU. In another embodiment, the PCIe switch 1120 may be located within the DPU 1140. The PCIe switch 1120 may manage the transfer of at least some data between the CPU 1110, the GPU 1130, and the DPU 1140. In another embodiment, the number of GPUs associated with the PCIe switch 1120 may be equal to the number of DPUs associated with the PCIe switch 1120. In at least one embodiment, the server 1102 may include, without limitation, any number of the CPUs 1110, the PCIe switches 1120, the GPUs 1130, and/or the DPUs 1140, in any combination. For example, in at least one embodiment, server 1102 could include eight, sixteen, thirty-two, and/or more GPUs 1130. In at least one embodiment, communication paths interconnecting various components, including but not limited to the CPU 1110, the PCIe switch 1120, the GPU 1130, and the DPU 1140, in FIG. 11 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1140 may include a network interface controller (NIC) 1142, a DDR memory 1144, and a non-volatile memory express (NVMe) device 1146. The NIC 1142 may be able to interface with a network 1104, which may also interface with additional NVMe devices available to the DPU 1140, such as over fabric. In an embodiment, the DPU 1140 may not include the NVMe device 1146. In another embodiment, the NVMe device 1146 may be located on the server 1102 and not on the DPU 1140. In yet another embodiment, the computing environment 1100 may include more than one of the NVMe device 1146, such as a first NVMe device in the DPU 1140 and a second first NVMe device on the server 1102 an associated directly with the PCIe switch 1120. In an embodiment, the DPU 1140 may not include the DDR memory 1144 and may include a computational storage services (CSS) in place of, or in addition to, the DDR memory 1144. For example, computing environment 1100 may include DPU computational storage (CS) memory 1106 available to the DPU 1140 as part of the CSS. The network 1104 may be able to interface with the DPU CS memory 1106 through the NIC 1142, according to any suitable interface protocol, such as remote direct memory access (RDMA) over Ethernet, InfiniBand, Fiber Channel, etc.

The total memory of the computing environment 1100 available for data storage may be expanded through the use of the DPU 1140 on nodes of the system. The DPU 1140 may have access to a pool 1150 of memory already available to the server 1102, such as double data rate (DDR) memory, on-board NVMe devices, NVMe devices over fabric, and CS. The pool 1150 of memory may include at least one of the DDR memory 1144, NVMe 1146, and the DPU CS memory 1106. The DPU 1140 may also be able to access the available memory of other DPUs as part of the pool 1150, and other DPUs may be able to access the available memory of DPU 1140, such as the pool 1150. This available memory can be accessed and utilized for data storage, without the addition of compute resources, such as compute nodes, which would be required using other solutions. The available pool 1150 accessible to the DPU 1140 may be provisioned for the server 1102 to expand the total memory available for data storage, such as to reduce the data storage load on the CPU 1110 or the GPU 1130, which can instead increase the utilization of their memory for processing. For example, during training of an AI, the model states, residual states, activation functions, and checkpoints can be stored, or offloaded, on the pool 1150 accessible to the DPU 1140.

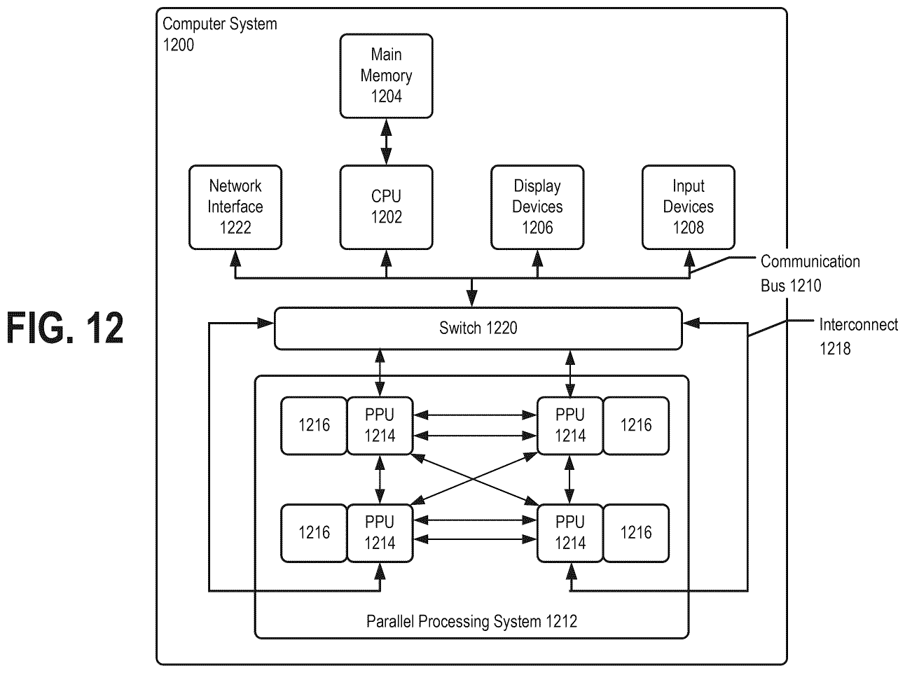

FIG. 12 illustrates a computer system 1200, according to at least one embodiment. In at least one embodiment, computer system 1200 comprises, without limitation, at least one central processing unit (“CPU”) 1202 that is connected to a communication bus 1210 implemented using any suitable protocol, such as PCI (“Peripheral Component Interconnect”), peripheral component interconnect express (“PCI-Express”), AGP (“Accelerated Graphics Port”), Hyper Transport, or any other bus or point-to-point communication protocol(s). In at least one embodiment, computer system 1200 includes, without limitation, a main memory 1204 and control logic (e.g., implemented as hardware, software, or a combination thereof) and data are stored in main memory 1204 which may take form of random access memory (“RAM”). One or more of the computing resources of the computer system 1200 is provided as part of an electronic device including an electronic module of an example embodiment. For example, various computing resources of the computer system 1200 may communicate with one another via high speed communication channels provided via mezzanine packages of respective electronic modules.

In at least one embodiment, a network interface subsystem (“network interface”) 1222 provides an interface to other computing devices and networks for receiving data from and transmitting data to other systems from computer system 1200.

In at least one embodiment, computer system 1200, in at least one embodiment, includes, without limitation, input devices 1208, parallel processing system 1212, and display devices 1206 which can be implemented using a conventional cathode ray tube (“CRT”), liquid crystal display (“LCD”), light emitting diode (“LED”), plasma display, or other suitable display technologies. In at least one embodiment, user input is received from input devices 1208 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1204 and/or secondary storage. Computer programs, if executed by one or more processors, enable system 1200 to perform various functions in accordance with at least one embodiment. memory 1204, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1202; parallel processing system 1212; an integrated circuit capable of at least a portion of capabilities of both CPU 1202; parallel processing system 1212; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1200 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1212 includes, without limitation, a plurality of parallel processing units (“PPUs”) 1214 and associated memories 1216. In at least one embodiment, PPUs 1214 are connected to a host processor or other peripheral devices via an interconnect 1218 and a switch 1220 or multiplexer. In at least one embodiment, parallel processing system 1212 distributes computational tasks across PPUs 1214 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1214, although such shared memory may incur performance penalties relative to use of local memory and registers resident to a PPU 1214. In at least one embodiment, operation of PPUs 1214 is synchronized through use of a command such as_syncthreads( ), wherein all threads in a block (e.g., executed across multiple PPUs 1214) to reach a certain point of execution of code before proceeding.

The PPUs 1214 may be in communication with one another and/or switch 1220 via one or more optical interconnects in accordance with example embodiments disclosed herein.

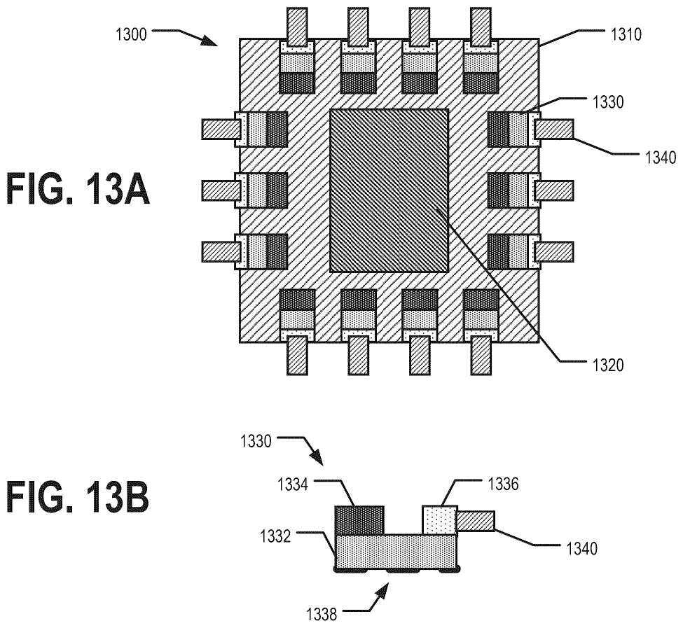

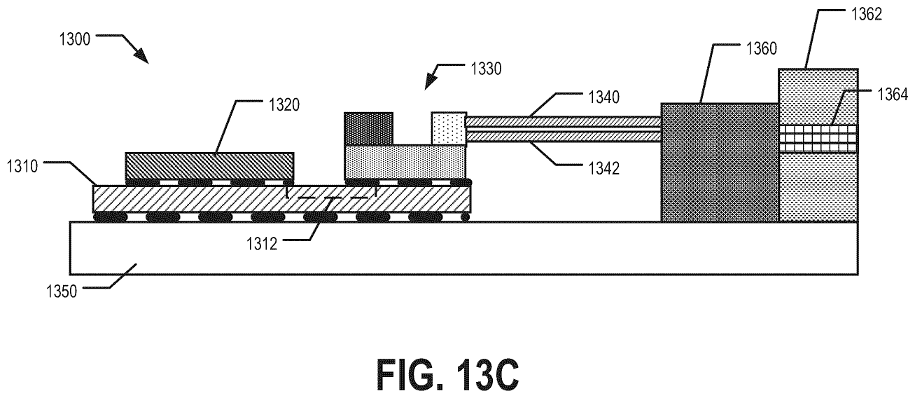

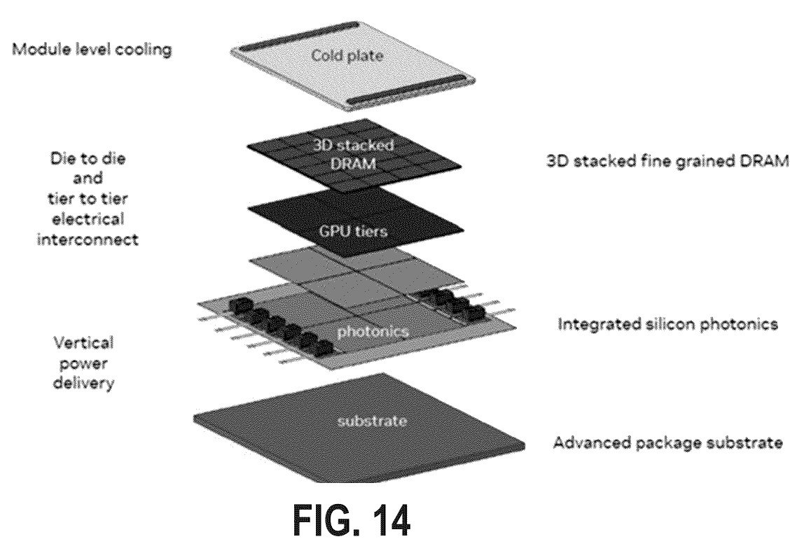

An example of a 2.5D IC package is shown in FIGS. 13A, 13B, and 13C. FIG. 13A is a top view of a 2.5D integrated co-packaged optics 1300 with the host ASIC 1320 on an organic substrate 1310 in accordance with an embodiment of the disclosure. A plurality of optical-electrical (OE) chiplets 1330 are disposed about the host ASIC 1320 and connected to the organic substrate 1310 via an microbump array 1338. As shown in FIG. 13B, each OE chiplet 1330 includes a electronic integrated circuit 1134 in communication with a silicon photonics photonic integrated circuit 1332 via hybrid bumps, for example. An OE chiplet 1330 further includes a fiber connector 1336 configured for receiving an optical fiber 1340 therein so as to optically couple the optical fiber 1340 to the silicon photonics photonic integrated circuit 1332. FIG. 13C is a cross-sectional view of the 2.5D integrated co-packaged optics 1300 with the host ASIC 1320 on the organic substrate 1310. The organic substrate 1310 is coupled to a switch mainboard 1350 via a BGA. The host ASIC 1320 is in communication with the OE chiplet 1330 via a chip-to-chip (e.g., C2C) interconnect over MCM 1312. One or more first optical fibers 1340 carry optical transmission and optical receiving signals between the OE chiplet 1330 and a fiber shuffle 1360 coupled to the line card front panel 1362, for example. External laser sources 1364 generate laser beams that are carried along one or more second optical fibers 1342. An example of a 3D IC package is shown in FIG. 14, which shows a dense 3D stacked module, which minimizes power overhead, in accordance with an embodiment of the disclosure.

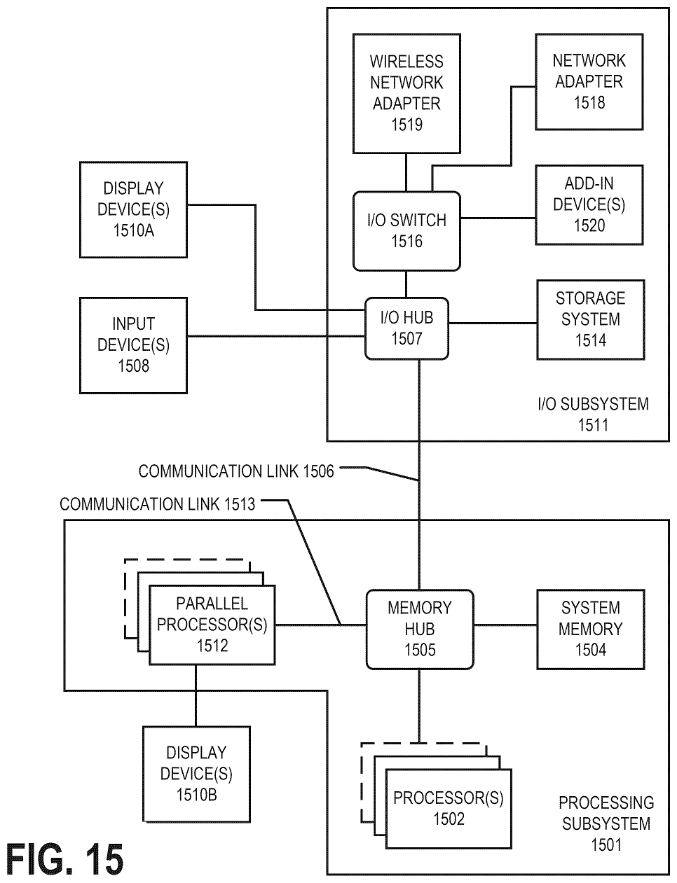

In at least one embodiment, as shown in FIG. 15, one or more parallel processor(s) 1512 incorporate circuitry optimized for graphics and video processing, including, for example, video output circuitry, and constitutes a graphics processing unit (“GPU”). In at least one embodiment, one or more parallel processor(s) 1512 incorporate circuitry optimized for general purpose processing. In at least embodiment, components of computing system 1500, which include various components shown in FIG. 15, may be integrated with one or more other system elements on a single integrated circuit. For example, in at least one embodiment, one or more parallel processor(s) 1512, memory hub 1505, processor(s) 1502, and I/O hub 1507 can be integrated into a SoC integrated circuit. In at least one embodiment, components of computing system 1500 can be integrated into a single package to form a system in package (“SIP”) configuration. In at least one embodiment, at least a portion of components of computing system 1500 can be integrated into a multi-chip module (“MCM”), which can be interconnected with other multi-chip modules into a modular computing system. In at least one embodiment, I/O subsystem 1511 and display devices 1510B are omitted from computing system 1500.

Some embodiments of the present disclosure are directed to a multi-chip module (MCM) with a centrally positioned main die and a plurality of peripherally positioned MCM sockets configured to mechanically receive and electrically connect mezzanine packages, which may include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate. As used herein, the terms “co-packaged optic” (or “CPO”) and “co-packaged copper” (or “CPC”) may refer to an advanced heterogeneous integration of either optics and silicon or copper and silicon, in which either integration may be implemented on a single packaged substrate. The CPO may utilize pluggable optical modules that include an optical engine (OE) to convert optical signals to electrical signals and electrical signals to optical signals. The CPO may further be comprised of an optical component on a photonics die and an electrical component on an electrical die.

As used herein, a ball grid array (BGA) may be a type of surface-mount packaging used for integrated circuits. BGA packages use an array of metallic conductor balls arranged in a grid to permanently mount devices such as microprocessors on a PCB. The metallic conductor balls may then undergo the reflow process described above, wherein the metallic conductor balls may be preheated, then melted to bond the IC to a substrate to form an IC package.

As used herein, the term “flip-chip (FC)” may refer to a method for interconnecting dies, such as semiconductor devices, IC chips, integrated passive devices, and microelectromechanical systems (MEMS), to external circuitry with solder bumps that have been deposited onto chip pads. The solder bumps may be deposited onto chip pads on the top side of the wafer during final wafer processing. The chip may be mounted to external circuitry (such as a circuit board or another chip or wafer) by “flipping” the chip, such that the chip's top side faces down and is positioned to allow the pads of the chip to align with matching pads on the external circuit. Solder is reflowed to complete the interconnect.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention, and that this invention is not limited to the specific constructions and arrangements shown and described, since various other changes, combinations, omissions, modifications, and substitutions, in addition to those set forth in the above paragraphs, are possible. Those skilled in the art will appreciate that various adaptations, modifications, and combinations of the just described embodiments may be configured without departing from the scope and spirit of the invention. For example, devices, modules, components, and/or elements shown in the figures are not necessarily drawn to scale and may vary from that shown without departing from the scope and spirit of the invention. Therefore, it is to be understood that, within the scope of the appended claims, the invention may be practiced other than as specifically described herein.

That which is claimed:

1. An electronic module, comprising:
a multi-chip module (MCM) substrate comprising a central portion configured to receive a main die;
a plurality of MCM sockets positioned about a peripheral portion of the MCM substrate; and
a plurality of mezzanine packages coupled to respective MCM sockets of the plurality of MCM sockets, the plurality of MCM sockets and the MCM substrate configured to enable communication of digital data between the main die and respective mezzanine packages of the plurality of mezzanine packages,
wherein the plurality of mezzanine packages comprises:
at least one co-packaged copper (CPC) package; and
at least one co-packaged optics (CPO) package.

2. The electronic module of claim 1, wherein at least one mezzanine package of the plurality of mezzanine packages is configured to be powered independent of the MCM substrate.

3. The electronic module of claim 2, wherein the MCM substrate is configured to be coupled to a system printed circuit board (PCB) and the at least one mezzanine package is configured to be powered via a direct electrical connection to the system PCB.

4. The electronic module of claim 1, wherein the MCM substrate is configured to be in electrical communication with a system PCB via a ball grid array (BGA) and at least one mezzanine package of the plurality of mezzanine packages is configured to be powered independent of the BGA.

5. The electronic module of claim 1, wherein the at least one CPC package comprises one or more radio-frequency copper cable connectors and the at least one CPO package comprises one or more optical devices.

6. The electronic module of claim 1, wherein each mezzanine package of the plurality of mezzanine packages comprises a respective mezzanine package substrate, the mezzanine package substrate comprises a connector portion configured to engage the MCM socket of the plurality of MCM sockets and a main portion configured to extend beyond the MCM substrate and configured to host one or more devices of the mezzanine package.

7. The electronic module of claim 6, wherein the MCM substrate is configured to be coupled to a system printed circuit board (PCB) and for at least one mezzanine package of the plurality of mezzanine packages, the one or more devices are powered via an electrical connection between the main portion of the mezzanine package substrate and the system PCB.

8. The electronic module of claim 6, wherein for at least one mezzanine package of the plurality of mezzanine packages, the one or more devices are configured to communicate data with the main die via engagement of the connector portion and the MCM socket.

9. The electronic module of claim 6, wherein the at least one CPO package comprises an input/output connection positioned on the main portion of the mezzanine package substrate, and wherein the input/output connection is configured to transmit input/output signals between the at least one CPO package and a system printed circuit board (PCB), wherein the MCM substrate is configured to be coupled to the system PCB.

10. The electronic module of claim 6, wherein for at least one mezzanine package of the plurality of mezzanine packages, the one or more devices are flip-chip mounted on the mezzanine package substrate.

11. The electronic module of claim 6, wherein, for the at least one CPO package, the one or more devices comprises one or more photonic integrated circuits (PICs).

12. The electronic module of claim 11, wherein the at least one CPO package comprises, for each PIC of the one or more PICS, an optical connector.

13. The electronic module of claim 6, further comprising a support member configured to be positioned between the main portion of the mezzanine package substrate and a system printed circuit board (PCB) to which the MCM substrate is coupled and to mechanically support the main portion of the mezzanine package substrate with respect to the system PCB.

14. The electronic module of claim 6, wherein each MCM socket of the plurality of MCM sockets comprises a socket frame defining a peripheral access opening configured to allow the main portion of the mezzanine package substrate to extend beyond an edge of the MCM socket.

15. The electronic module of claim 1, further comprising the main die positioned on the central portion of the MCM substrate.

16. The electronic module of claim 1, wherein each MCM socket of the plurality of MCM sockets comprises a socket pin array configured to electrically connect a respective mezzanine package of the plurality of mezzanine packages to the main die via at least one electrical trace of the MCM substrate.

17. The electronic module of claim 16, wherein the MCM substrate is configured to be in electrical communication with a system printed circuit board (PCB) via a ball grid array (BGA) and a pitch of the BGA is greater than a pitch of the socket pin array.

18. The electronic module of claim 1, wherein at least a subset of the plurality of mezzanine packages are configured for at least one of receiving digital data to be provided to the main die or transmitting digital data provided by the main die.

19. The electronic module of claim 1, wherein each MCM socket of the plurality of MCM sockets is configured to electrically connect high speed signal pins and ground isolation pins of a respective mezzanine package of the plurality of mezzanine packages to corresponding components of the MCM substrate and the MCM socket is free of power rails.

20. The electronic module of claim 1, wherein at least one MCM socket of the plurality of MCM sockets is configured to have a mezzanine package coupled thereto wherein the mezzanine package is selected from a group consisting of a co-packaged copper (CPC) package and a co-packaged optics (CPO) package.
